(19) United States
(12) Patent Application Publication
(10) Pub. No.: US 2024/0258302 A1
(43) Pub. Date: Aug. 1, 2024

(54) SEMICONDUCTOR DIE PACKAGE AND METHODS OF FORMATION

(71) Applicant: Taiwan Semiconductor Manufacturing Company, Ltd., Hsinchu (TW)

(72) Inventors: Shu-Hui SU, Tucheng City (TW); Hsin-Li CHENG, Hsin Chu (TW); YingKit Felix TSUI, Cupertino, CA (US)

(21) Appl. No.: 18/162,318

(22) Filed: Jan. 31, 2023

(51) Int. Cl. H01L 27/02; H01L 23/00; H01L 23/522

(52) U.S. Cl. CPC H01L 27/0292; H01L 23/5223; H01L 24/08; H01L 24/80; H01L 27/0255; H01L 2224/08145; H01L 2224/08235; H01L 2224/80895; H01L 2224/80896; H01L 2924/1203; H01L 2924/1205; H01L 2924/1431

(57) ABSTRACT

Some implementations herein describe apparatuses and techniques related to a semiconductor die package including a first integrated circuit die including capacitor circuitry bonded with a second integrated circuit die including logic circuitry. The semiconductor die package may include discharge paths incorporated into a seal ring structure spanning the first integrated circuit die and the second integrated circuit die. The discharge paths may lead to a power management integrated circuit included in the second integrated circuit die. During a bonding of the first integrated circuit die and the second integrated circuit die, the discharge paths incorporated into the seal ring structure may route an electrical discharge from the capacitor circuitry of the first integrated circuit die to the power management integrated circuit.

### BACKGROUND

Various semiconductor device packing techniques may be used to incorporate one or more semiconductor dies into a semiconductor device package. In some cases, semiconductor dies may be stacked in a semiconductor device package to achieve a smaller horizontal or lateral footprint of the semiconductor device package and/or to increase the density of the semiconductor device package. Semiconductor device packing techniques that may be performed to integrate a plurality of semiconductor dies in a semiconductor device package may include integrated fanout (InFO), package on package (PoP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example semiconductor die package described herein.

FIGS. 3A-3C are diagrams of an example implementation of the semiconductor die package described herein.

FIG. 4 is an example implementation of the semiconductor die package described herein.

FIGS. 5A and 5B are diagrams of an example implementations of a trench capacitor structure described herein.

FIGS. 6A-6E are diagrams of an example implementation of forming a semiconductor die described herein.

FIGS. 7A-7E are diagrams of an example implementation of forming a semiconductor die described herein.

FIGS. 8A-8E are diagrams of an example implementation of forming a semiconductor die described herein.

FIGS. 9A-9E are diagrams of an example implementation of forming a semiconductor die described herein.

FIGS. 10A-10G are diagrams of an example implementation of forming a portion of a semiconductor die package described herein.

FIG. 11 is a diagram of example components of a device described herein.

FIG. 12 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a semiconductor die package, semiconductor dies may be directly bonded such that the semiconductor dies are vertically arranged. Examples of semiconductor die packages that include vertically arranged semiconductor dies include a wafer on wafer (WoW) semiconductor die package, a chip on wafer (CoW) semiconductor die package, or a die to die direct bonded semiconductor die package), among other examples. The use of direct bonding and vertical stacking of dies may reduce interconnect lengths between the semiconductor dies (which reduces power loss and signal propagation times) and may enable increased density of semiconductor die packages in a semiconductor device package that includes the semiconductor die package.

In some cases, the semiconductor die package includes two or more integrated circuit (IC) dies. For example, the semiconductor die package may include a first IC die including capacitor circuitry (e.g., deep trench capacitor circuitry) bonded to a second IC die including logic circuitry. Electrostatic charges may build up in the semiconductor die package during processing operations to manufacture the capacitor circuitry, which may result in an electrical charge being accumulated in the capacitor circuitry. If the electrical charge is retained in the capacitor circuitry during the bonding process to bond the first IC die and the second IC die, the electrical charge may discharge and damage the logic circuitry of the second IC die. The damaged logic circuitry may result in reduced performance for the semiconductor die package and/or may result in the semiconductor die package being scrapped, which reduces semiconductor die package yield.

Some implementations herein describe a semiconductor die package (and associated methods of formation) that includes an electrostatic discharge (ESD) protection circuit that is configured to provide a safe path in the semiconductor die package for discharging electrical charges that may accumulate in capacitor circuitry of the semiconductor die package. The semiconductor die package may include a first IC die bonded with a second IC die. The first IC die may include capacitor circuitry, and the second IC die may include logic circuitry. The ESD protection circuit may include discharge paths incorporated into a seal ring structure spanning the first IC die and the second IC die. The discharge paths may electrically connect the capacitor circuitry of the first IC die to a power management integrated circuit (PMIC), of the ESD protection circuit, included in the second IC die. During a bonding of the first IC die and the second IC die, the discharge paths incorporated into the seal ring structure may route an electrical charge from the capacitor circuitry of the first IC die to the PMIC, as opposed to the electric charge being discharged through the logic circuitry.

By including the ESD protection circuit in the semiconductor die package, a likelihood of damage to the logic circuitry of the second IC die during the bonding operation may be reduced relative to another semiconductor device not including the discharge paths. Further, and in this way, an amount of resources to manufacture a quantity of the semiconductor device (e.g., manufacturing tools, materials, and/or computing resources, among other examples) may be reduced in that yield of semiconductor die packages may be increased as a result of reduced scrapping of semiconductor die packages.

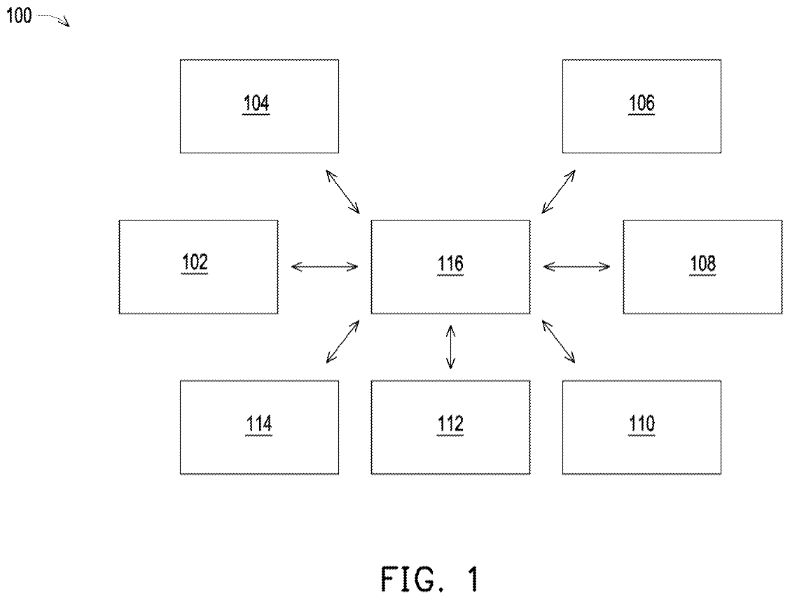

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 may be a direct bonding tool that is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

In some implementations, one or more of the semiconductor processing tools 102-116 and/or the wafer/die transport tool 116 may perform one or more semiconductor processing operations described herein. For example, one or more of the semiconductor processing tools 102-114 and/or the wafer/die transport tool 116 may perform a series of one or more operations to form a first IC die that includes a trench capacitor and a portion of a seal ring structure. The series of one or more operations may form a second IC die that includes a power management integrated circuit. The series of one or more operations may join the first IC die and the second IC die to form a stacked-die device including a discharge path between the trench capacitor and the power management integrated circuit, where the discharge path includes the portion of the seal ring structure.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

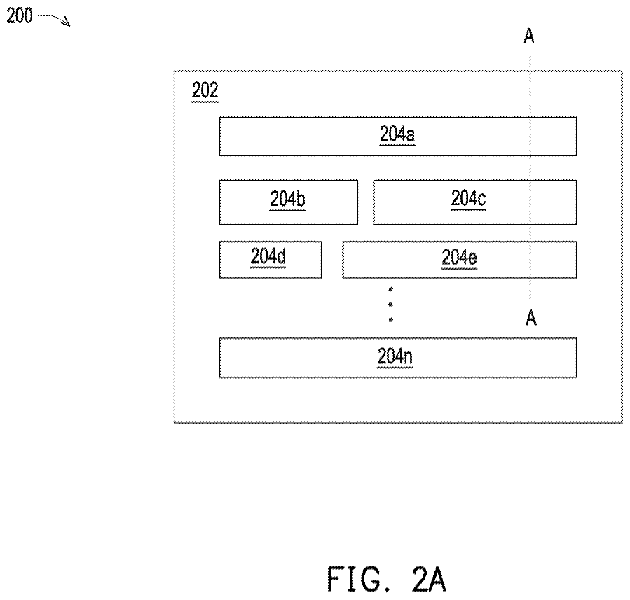

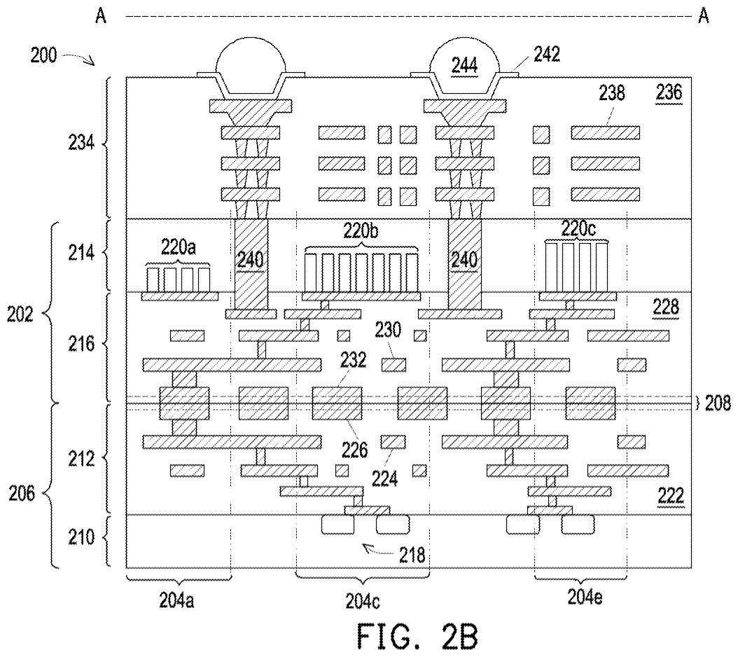

FIGS. 2A and 2B are diagrams of an example semiconductor die package 200 described herein. The semiconductor die package 200 includes an example of a wafer on wafer (WoW) semiconductor die package, a die on wafer semiconductor die package, a die on die semiconductor die package, or another type of semiconductor die package in which semiconductor dies are directly bonded and vertically arranged or stacked. FIG. 2A illustrates a top-down view of a portion of the semiconductor die package 200. FIG. 2B illustrates a cross-section view of a portion of the semiconductor die package 200 along line A-A in FIG. 2A.

As shown in FIG. 2A, the semiconductor die package 200 may include a first semiconductor die 202 and a plurality of trench capacitor regions 204a-204n in the first semiconductor die 202. The trench capacitor regions 204a-204n may be horizontally arranged in the first semiconductor die 202. The trench capacitor regions 204a-204n may include various sizes and/or shapes to provide a sufficient amount of decoupling capacitance across the semiconductor die package 200 for the circuits and semiconductor devices of the semiconductor die package 200.

As shown in FIG. 2B, the semiconductor die package 200 includes the first semiconductor die 202 and a second semiconductor die 206. In some implementations, the semiconductor die package 200 includes additional semiconductor dies. The first semiconductor die 202 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the first semiconductor die 202 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The second semiconductor die 206 may include the same type of semiconductor die as the first semiconductor die 202, or may include a different type of semiconductor die.

The first semiconductor die 202 and the second semiconductor die 206 may be bonded together (e.g., directly bonded) at a bonding interface 208. In some implementations, one or more layers may be included between the first semiconductor die 202 and the second semiconductor die 206 at the bonding interface 208, such as one or more passivation layers, one or more bonding films, and/or one or more layers of another type.

The second semiconductor die 206 may include a device region 210 and an interconnect region 212 adjacent to and/or above the device region 210. In some implementations, the second semiconductor die 206 may include additional regions. Similarly, the first semiconductor die 202 may include a device region 214 and an interconnect region 216 adjacent to and/or below the device region 214. In some implementations, the first semiconductor die 202 may include additional regions. The first semiconductor die 202 and the second semiconductor die 206 may be bonded at the interconnect region 212 and the interconnect region 216. The bonding interface 208 may be located at a first side of the interconnect region 216 facing the interconnect region 212 and corresponding to a first side of the second semiconductor die 202.

The device regions 210 and 214 may each include a semiconductor substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The device region 210 of the second semiconductor die 206 may include one or more semiconductor devices 218 included in the semiconductor substrate of the device region 210. The semiconductor devices 218 may include one or more transistors (e.g., planar transistors, fin field effect transistors (FinFETs), nanosheet transistors (e.g., gate all around (GAA) transistors), memory cells, capacitors, inductors, resistors, pixel sensors, circuits (e.g., integrated circuits (ICs)), and/or another type of semiconductor devices. In some implementations, the device region 210 includes logic circuitry.

As further shown in FIG. 2B, the device region 214 of the first semiconductor die 202 may include a plurality of trench capacitor structure 220a-220c in the semiconductor substrate of the device region 214. Respective pluralities of the trench capacitor structure 220a-220c may be included in different trench capacitor regions in the device region 214. For example, the trench capacitor structure 220a may be included in the trench capacitor region 204a, the trench capacitor structure 220b may be included in the trench capacitor region 204c, the trench capacitor structure 220c may be included in the trench capacitor region 204e, and so on. The trench capacitor structure 220a-220c may be configured to provide a decoupling capacitance for the one or more semiconductor devices 218 of the second semiconductor die 206.

At least two or more of the respective pluralities of trench capacitor structure 220a-220c may be formed to different depths (or heights) in the device region 214 relative to a surface (e.g., the bottom surface) of the semiconductor substrate of the device region 214. For example, a depth (or height) of the trench capacitor structure 220b in the trench capacitor region 204c may be greater relative to a depth (or height) of the trench capacitor structure 220a in the trench capacitor region 204a. As another example, a depth (or height) of the trench capacitor structure 220c in the trench capacitor region 204e may be greater relative to the depth (or height) of the trench capacitor structure 220c in the trench capacitor region 204c, and may be greater relative to the depth (or height) of the trench capacitor structure 220a in the trench capacitor region 204a. In some implementations, the trench capacitor structures included in the same trench capacitor region may be formed to the same depth (or the same height). In some implementations, two or more trench capacitor structures included in the same trench capacitor region may be formed to different depths (or different heights).

The depths of the trench capacitor structure 220a-220c (and other trench capacitor structures in the trench capacitor regions 204a-204n) may be selected to provide sufficient capacitance so as to satisfy circuit decoupling parameters for the semiconductor devices 218 included in circuits of the semiconductor die package 200, while reducing the likelihood of warping, breaking, and/or cracking of the semiconductor die package 200. Some of the circuits of the semiconductor die package 200 may have greater decoupling capacitance requirements than other circuits in order to properly operate at desired performance parameters. Accordingly, deeper trench capacitor structures may be formed for these circuits relative to the depth of trench capacitor structures that are formed for other circuits that have lesser decoupling capacitance requirements. This enables a balance between satisfying capacitance requirements in the semiconductor die package 200 and reducing the likelihood of warpage in the semiconductor die package 200.

Additionally and/or alternatively, the arrangement or layout of trench capacitor structure depths (or heights) across the semiconductor die package 200 may be determined or selected based on the overall floorplan of the first semiconductor die 202 and/or the second semiconductor die 206. For example, trench capacitor structures of greater depth (or greater height) may be included at or near an edge (e.g., an outer edge or an outer perimeter) of the first semiconductor die 202 and/or the second semiconductor die 206 to reduce the likelihood of warpage in the first semiconductor die 202 and/or the second semiconductor die 206. Trench capacitor structures of lesser depth (or lesser height) may be included closer to the center of the first semiconductor die 202 and/or the second semiconductor die 206. However, other arrangements of trench capacitor structure depths (or heights) across the semiconductor die package 200 may be selected to satisfy an equivalent series resistance (ESR) parameter for the interconnection regions 212 and 216, among other performance parameters.

Various design rules and/or principals may be employed when determining the arrangement or layout of trench capacitor structure depths (or heights) across the semiconductor die package 200. In some implementations, a target trench capacitor structure depth (or height) may be selected for the semiconductor die package 200, and the depths (or heights) of the trench capacitor structures across the semiconductor die package 200 may be selected within a particular range of the target trench capacitor structure depth (or height). As an example, a target trench capacitor structure depth (or height) may be selected for the semiconductor die package 200, and the depths (or heights) of the trench capacitor structures across the semiconductor die package 200 may be selected from a range of approximately +/−15% of the target trench capacitor structure depth (or height). However, other values for the range are within the scope of the present disclosure.

In some implementations, other parameters for the trench capacitor structures of the semiconductor die package 200 may be selected in a similar manner. For example, a target trench capacitor structure width (or critical dimension) may be selected for the semiconductor die package 200, and the widths (or critical dimensions) of the trench capacitor structures across the semiconductor die package 200 may be selected from a range of approximately +/−30% of the target trench capacitor structure depth (or height). However, other values for the range are within the scope of the present disclosure.

As another example, a target trench capacitor structure aspect ratio (e.g., a ratio of the height to the width) may be selected for the semiconductor die package 200, and the aspect ratios of the trench capacitor structures across the semiconductor die package 200 may be selected from a range of approximately +/−12% of the target trench capacitor structure depth (or height). However, other values for the range are within the scope of the present disclosure.

The interconnect regions 212 and 216 may be referred to as back end of line (BEOL) regions. The interconnect region 212 may include one or more dielectric layers 222, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 222. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 212 may further include metallization layers 224 in the one or more dielectric layers 222. The semiconductor devices 218 in the device region 210 may be electrically connected and/or physically connected with one or more of the metallization layers 224. The metallization layers 224 may include conductive lines, trenches, vias, pillars, interconnects, and/or another type of metallization layers. Contacts 226 may be included in the one or more dielectric layers 222 of the interconnect region 212. The contacts 226 may be electrically connected and/or physically connected with one or more of the metallization layers 224. The contacts 226 may include conductive terminals, conductive pads, conductive pillars, under bump metallization (UBM) structures, and/or another type of contacts. The metallization layers 224 and the contacts 226 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 216 may include one or more dielectric layers 228, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 228. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 216 may further include metallization layers 230 in the one or more dielectric layers 228. The trench capacitor structure 220a-220c in the device region 214 may be electrically connected and/or physically connected with one or more of the metallization layers 230. The metallization layers 230 may include conductive lines, trenches, vias, pillars, interconnects, and/or another type of metallization layers. Contacts 232 may be included in the one or more dielectric layers 228 of the interconnect region 216. The contacts 232 may be electrically connected and/or physically connected with one or more of the metallization layers 230. Moreover, the contacts 232 may be electrically and/or physically connected with the contacts 226 of the second semiconductor die 206. The contacts 232 may include conductive terminals, conductive pads, conductive pillars, UBM structures, and/or another type of contacts. The metallization layers 230 and the contacts 232 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

As further shown in FIG. 2B, the semiconductor die package 200 may include a redistribution structure 234. The redistribution structure 234 may include a redistribution layer (RDL) structure, an interposer, a silicon-based interposer, a polymer-based interposer, and/or another type of redistribution structure. The redistribution structure 234 may be configured to fan out and/or route signals and I/O of the semiconductor dies 202 and 206.

The redistribution structure 234 may include one or more dielectric layers 236 and a plurality of metallization layers 238 disposed in the one or more dielectric layers 236. The dielectric layer(s) 236 may include polybenzoxazole (PBO), a polyimide, a low temperature polyimide (LTPI), an epoxy resin, an acrylic reason, a phenol resin, benzocyclobutene (BCB), one or more dielectric layers, and/or another suitable dielectric material.

The metallization layers 238 of the redistribution structure 234 may include one or more materials such as a gold (Au) material, a copper (Cu) material, a silver (Ag) material, a nickel (Ni) material, a tin (Sn) material, and/or a palladium (Pd) material, among other examples. The metallization layers 238 of the redistribution structure 234 may include metal lines, vias, interconnects, and/or another type of metallization layers.

As further shown in FIG. 2B, the semiconductor die package 200 may include one or more backside through silicon via (BTSV) structures 240 through the device region 210, and into a portion of the interconnect region 216 of the first semiconductor die 202. The one or more BTSV structures 240 may include vertically elongated conductive structures (e.g., conductive pillars, conductive vias) that electrically connect one or more of the metallization layers 230 in the interconnect region 216 of the first semiconductor die 202 to one or more metallization layers 238 in the redistribution structure 234. The BTSV structures 240 may be referred to as through silicon via (TSV) structures in that the BTSV structures 240 extend fully through a semiconductor substrate (e.g., a silicon substrate) of the device region 214 as opposed to extending fully through a dielectric layer or an insulator layer. The one or more BTSV structures 240 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

UBM layers 242 may be included on a top surface of the one or more dielectric layers 236. The UBM layers 242 may be electrically connected and/or physically connected with one or more metallization layers 238 in the redistribution structure 234. The UBM layers 242 may be included in recesses in the top surface of the one or more dielectric layers 236. The UBM layers 242 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

As further shown in FIG. 2B, the semiconductor die package 200 may include conductive terminals 244. The conductive terminals 244 may be electrically connected and/or physically connected with the UBM layers 242. The UBM layers 242 may be included to facilitate adhesion to the one or more metallization layers 238 in the redistribution structure 234, and/or to provide increased structural rigidity for the conductive terminals 244 (e.g., by increasing the surface area to which the conductive terminals 244 are connected). The conductive terminals 244 may include ball grid array (BGA) balls, land grid array (LGA) pads, pin grid array (PGA) pins, and/or another type of conductive terminals. The conductive terminals 244 may enable the semiconductor die package 200 to be mounted to a circuit board, a socket (e.g., an LGA socket), an interposer or redistribution structure of a semiconductor device package (e.g., a chip on wafer on substrate CoWoS package, an integrated fanout (InFO) package), and/or another type of mounting structure. a

As indicated above, FIGS. 2A and 2B are provided as an example. Other examples may differ from what is described with regard to FIGS. 2A and 2B.

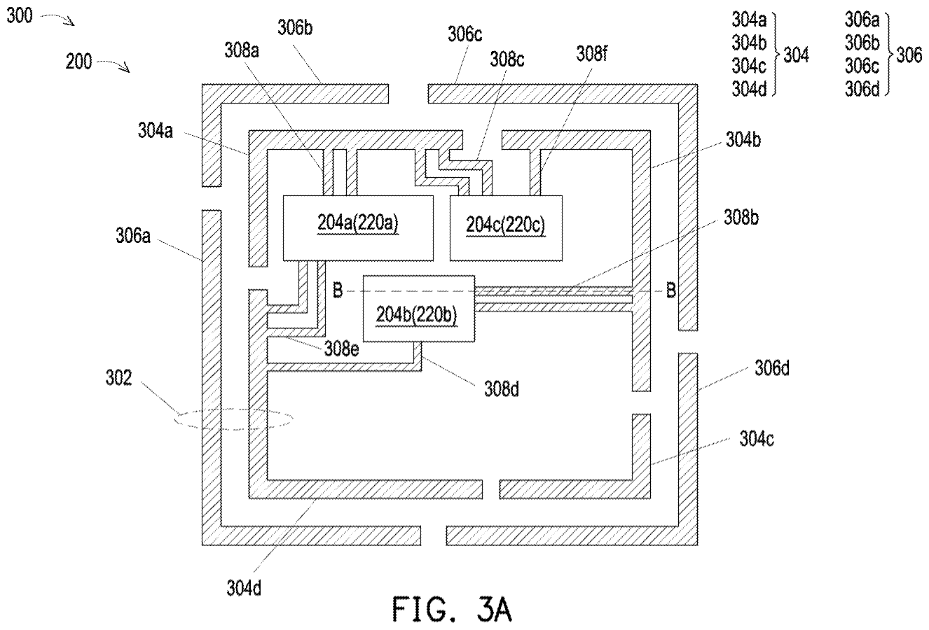

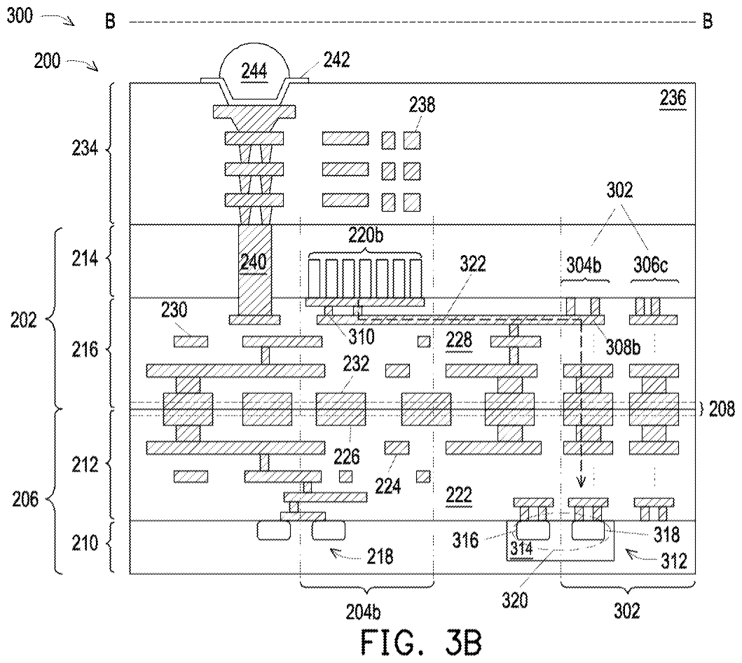

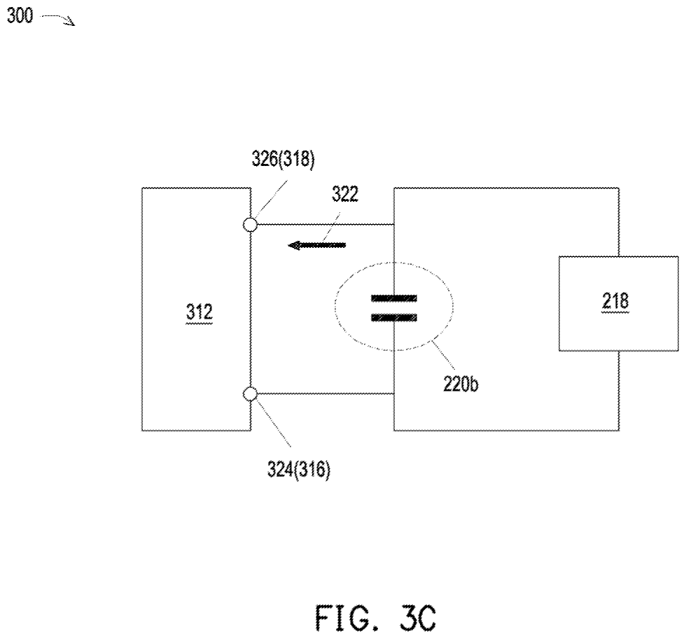

FIGS. 3A-3C are diagrams of an example implementation 300 of the semiconductor die package 200 described herein. The example implementation 300 includes a portion of the semiconductor die package 200 that includes aspects of a trench capacitor, a power management integrated circuit (PMIC), and a discharge path between the trench capacitor and the PMIC. FIG. 3A illustrates a plan view of another portion of the semiconductor die package 200. FIG. 3B illustrates a cross-section view of the other portion of the semiconductor die package 200 along line B-B in FIG. 3A. FIG. 3C illustrates an electrical schematic corresponding to features described in FIGS. 3A and 3B.

As shown in the top plan view of FIG. 3A, the portion of the semiconductor die package 200 in the example implementation 300 includes a seal ring structure 302. The seal ring structure 302 may be included around the perimeter (e.g., the outer perimeter) of the semiconductor die package 200. The seal ring structure 302 may be configured to provide increased structural rigidity for the semiconductor die package 200, which may reduce the likelihood of cracking, warpage, and/or another type of physical damage that might otherwise result from physical stresses that are exerted on the semiconductor die package 200. Additionally, and/or alternatively, the seal ring structure 302 may be configured to provide a humidity seal for the semiconductor die package 200. Thus, the seal ring structure 302 may reduce the likelihood of humidity ingress in the semiconductor die package 200, which might otherwise result in oxidation and/or physical deterioration of the semiconductor die package 200.

As further shown in FIG. 3A, the seal ring structure 302 may include an inner seal ring structure 304 and an outer seal ring structure 306. The inner seal ring structure 304 may include a plurality of segmented metallization layers 304a-304d (e.g., inner seal ring segments). The outer seal ring structure 306 may include a plurality of segmented metallization layers 306a-306d (e.g., outer seal ring segments).

FIG. 3A shows trench capacitor regions 204a-204c that may each be electrically connected with the inner seal ring structure 304 by a respective metallization layer 308a-308f (e.g., a respective electrically conductive trace). Additionally, or alternatively, each of the one or more trench capacitor regions 204a-204c includes a corresponding trench capacitor structure (e.g., the corresponding trench capacitor structure 220a-220c). In some implementations, and as an example, capacitances of the trench capacitor structures 220a-220c are included in a range of approximately 5 micro farads (μF) to approximately 200 μF. However, other values and ranges for the capacitances of the trench capacitor structures 204a-204c are within the scope of the present disclosure.

Using the trench capacitor structure 220b and the metallization layer 308b as an example, FIGS. 3B and 3C provide additional details of connecting a trench capacitor structure to a PMIC circuit (e.g., one or more of the trench capacitor structures 220a-220c may be connected to the PMIC circuit through the metallization layers 308a-308f using techniques similar to those detailed in FIGS. 3B and 3C). In some implementations, segmentation of different metallization layers provides for a combination of discharge paths having different electrical characteristics (e.g., a discharge path corresponding to a positive polarity/Vdd (drain voltage) and/or another discharge path corresponding to a negative polarity/Vss (source voltage), among other examples).

As shown in the section view of FIG. 3B, the portion of the semiconductor die package 200 illustrated in the example implementation 300 may include components 202-244 similar to those illustrated and described above in connection with FIGS. 2A-2C. As further shown in FIG. 3B, the portion of the semiconductor die package 200 illustrated in the example implementation 300 may include the seal ring structure 302, including the segmented metallization layer 304b and the segmented metallization layer 306c. The seal ring structure 302 may extend between the device region 210 of the second semiconductor die 206 and the device region 214 of the first semiconductor die 202. Moreover, the seal ring structure 302 may extend through the interconnect region 212 of the second semiconductor die 206 and through the interconnect region 216 of the first semiconductor die 202. The seal ring structure 302 may include metallization layers 224 and contacts 226 included in the interconnect region 212, and may include metallization layers 230 and contacts 232 included in the interconnect region 216.

As further shown in FIG. 3B, the trench capacitor structure 220b in the trench capacitor region 204b may be electrically connected and/or physically connected with the segmented metallization layer 304b (e.g., the inner seal ring structure 304) by the metallization layer 308b (e.g., an electrical trace). The metallization layer 308b may be included in the interconnect region 216 of the first semiconductor die 202. Conductive lines 310 under the trench capacitor structure 220 may electrically connect the metallization layer 308b with a metallization layer 230, which may electrically connect the trench capacitor structure 220 with the conductive lines 310.

As further shown in FIG. 3B, the segmented metallization layer 304b (e.g., the inner seal ring structure 304) may be electrically connected and/or physically connected with a power management integrated circuit (PMIC) 312 that is included in the semiconductor substrate of the device region 210 of the second semiconductor die 206. The segmented metallization layer 304b (e.g., the inner seal ring structure 304) electrically connects the PMIC 312 with the trench capacitor structure 220b in the trench capacitor region 204b.

The PMIC 312 may be configured to provide the one or more semiconductor devices 218 (e.g., logic circuitry) with ESD protection (e.g., protection against electrostatic buildup that may occur during assembly of a WoW product). One or more regions of the semiconductor substrate of the device region 210 may be doped to form an n-well 314. N-type contacts 316 and p-type contacts 318 of one or more diode structures 320 (e.g., may be included within the PMIC 312.

As shown in FIG. 3B, one or more portions of the segmented metallization layer 304b (e.g., the inner seal ring structure 304) may be included as part of a discharge path 322 between the trench capacitor structure 220b and the PMIC 312. In some implementations, the discharge path 322 may route an electrical discharge from the trench capacitor structure 220b to the PMIC 312. The discharge path 322 may reduce a likelihood of damage to one or more devices in the semiconductor die package 200 (e.g., the one or more semiconductor devices 218 including logic circuitry, among other examples) during a WoW bonding operation may be reduced relative to another semiconductor die package not including the discharge path 322. Further, and due to the reduction in the likelihood of damage (e.g., corresponding to a reduction in a yield of the semiconductor die package 200), an amount of resources to manufacture a quantity of the semiconductor die package 200 (e.g., manufacturing tools, materials, and/or computing resources, among other examples) may be reduced.

The portions of the segmented metallization layer 304b may include one or more conductive strips or layers. The quantity of conductive strips or layers may be dependent on depth in the first semiconductor die 202. For example, at a first depth, the segmented metallization layer 304b may include a single conductive strip, as shown in FIG. 3A and as shown near the bonding interface 208 in FIG. 3B. As another example, the segmented metallization layer 304b may include a plurality of conductive strips near an interface between the device region 214 and the interconnect region 216.

FIG. 3C shows an example schematic of the implementation 300. The schematic includes an electrical schematic of an electrostatic discharge (ESD) protection circuit described herein. As shown, the semiconductor device 218 (e.g., logic circuitry) connects with a trench capacitor structure 220b of the ESD protection circuit. The trench capacitor structure 220b may be configured to electrically decouple the semiconductor device 218 from other logic circuitry of the second semiconductor die 206. For example, the trench capacitor structure 220b may absorb voltage spikes in the semiconductor device 218, may absorb electrical noise from the semiconductor device 218, and/or may provide another type of electrical decoupling for the semiconductor device 218. Additionally, and as shown in FIG. 3C, the trench capacitor structure 220b connects with the PMIC 312 of the ESD protection circuit. The electrical currents that are absorbed and/or accumulated by the trench capacitor structure 220b may be discharged through the PMIC 312 as opposed to through other semiconductor devices of the second semiconductor die 206. The trench capacitor structure 220b may connect with a negative polarity terminal 324 of the PMIC 312 (e.g., a Vₛₛ (a diode source voltage) terminal and/or the n-type contact 316, among other examples). Additionally, or alternatively, the trench capacitor structure 220b may connect to a positive polarity terminal 326 of the PMIC 312 (e.g., a V_{dd} (a diode drain voltage) terminal and/or the p-type contact 318, among other examples).

In some implementations, and based on a polarity of a charge dissipated by the trench capacitor structure 220b, a route of the discharge path 322 within the semiconductor die package 200 may change. For example, and as shown in FIG. 3C, if the charge dissipated by the trench capacitor structure 220b is a negative charge, the discharge path 322 of the charge may be through the positive polarity terminal 326. As another example, if the polarity of the charge dissipated by the trench capacitor structure 220b is a positive charge, the discharge path 322 may be through the negative polarity terminal 324.

An example configuration of the semiconductor die package 200, in context of features described in FIGS. 3A-3C (and FIGS. 2A and 2B), may include a first IC die (e.g., the IC die 202). The first IC die includes a first trench capacitor (e.g., the trench capacitor structure 220a), a second trench capacitor (e.g., the trench capacitor structure 220c), a first seal ring segment (e.g., the metallization layer 304a), and a second seal ring segment (e.g., the metallization layer 304d) that is electrically isolated from the first seal ring segment. The semiconductor die package 200 includes a second IC die (e.g., the IC die 206) connected with the first IC die. The second IC die includes the PMIC 312. The PMIC 312 includes a first voltage terminal (e.g., the negative polarity terminal 324) corresponding to a first polarity and a second voltage terminal (e.g., the positive polarity terminal 326) corresponding to a second polarity that is opposite the first polarity. The semiconductor die package 200 includes a first electrically conductive trace (e.g., the metallization layer 308a) connecting the first trench capacitor, the first seal ring segment, and the first voltage terminal. The semiconductor die package 200 includes a second electrically conductive trace (e.g., the metallization layer 308e) connecting the first trench capacitor, the second seal ring segment, and the second voltage terminal. The semiconductor die package includes a third electrically conductive trace (e.g., the electrically conductive trace 308c) connecting the second trench capacitor, the first seal ring segment, and the first voltage terminal.

As indicated above, FIGS. 3A-3C are provided as an example. Other examples may differ from what is described with regard to FIGS. 3A-3C.

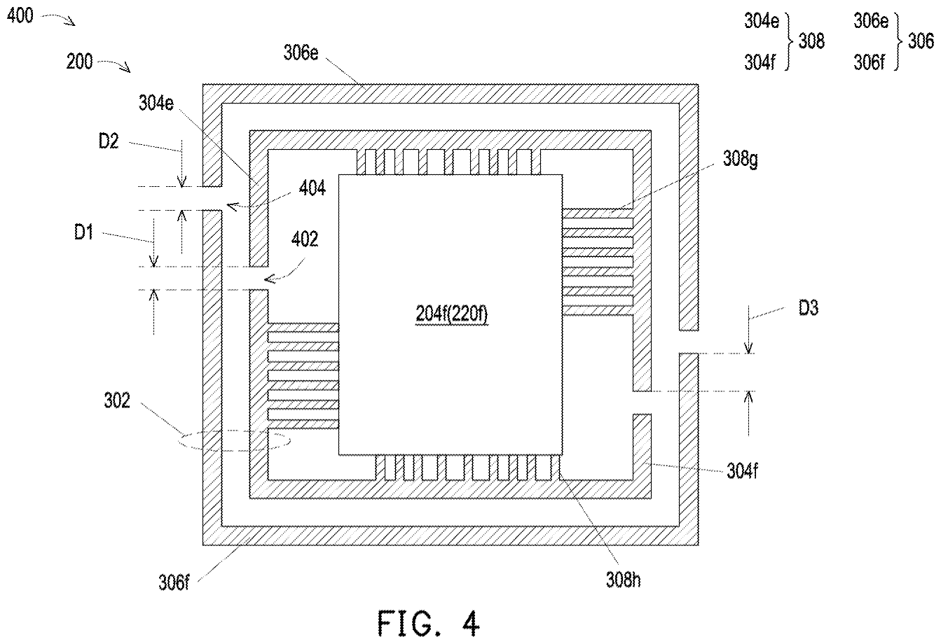

FIG. 4 is a diagram of an example implementation 400 of the semiconductor die package 200 described herein. As shown in FIG. 4, the portion of the semiconductor die package 200 in the example implementation 400 includes the seal ring structure 302. Further, and in contrast to the example implementation 300 of FIGS. 3A-3C, the example implementation 400 includes a single trench capacitor region 204f (including a single corresponding trench capacitor structure 220f). In some implementations, and as an example, a capacitance of the trench capacitor structure 220f may be included in a range of approximately 500 μF to approximately 1000 μF. However, other values and ranges for the capacitance of the trench capacitor structure 220f are within the scope of the present disclosure.

As shown in the top plan view in FIG. 4, the seal ring structure 302 may include an inner seal ring structure 304 and an outer seal ring structure 306. The inner seal ring structure 304 may include a plurality of segmented metallization layers 304e and 304f (e.g., inner seal ring segments). Additionally, or alternatively, the outer seal ring structure 306 may include a plurality of segmented metallization layers 306e and 306f (e.g., outer seal ring segments).

As shown in FIG. 4, the segmented metallization layers 304e and 304f are spaced apart by a gap 402. In some implementations, a width D1 of the gap may be included in a range of approximately 0.3 microns (μm) to approximately 0.5 μm. If the width D1 is less than 0.3 μm cracking may occur to the seal ring structure 302 during a dicing operation and cause moisture penetration into the semiconductor die package 200. If the width D1 is greater than approximately 0.5 μm, the segmented metallization layers 304e and 304f may be separated too far to effectively protect the semiconductor die package 200 from moisture penetration. However, other values and ranges for the width D1 are within the scope of the present disclosure.

Also as shown in FIG. 4, the segmented metallization layers 306e and 306f are spaced apart by a gap 404. In some implementations, a width D2 of the gap may be included in a range of approximately 0.3 microns (μm) to approximately 0.5 μm. If the width D2 is less than 0.3 μm cracking may occur to the seal ring structure 302 during a dicing operation and cause moisture penetration into the semiconductor die package 200. If the width D2 is greater than approximately 0.5 μm, the segmented metallization layers 306e and 306f may be separated too far to effectively protect the semiconductor die package 200 from moisture penetration. However, other values and ranges for the width D2 are within the scope of the present disclosure.

Portions of the seal ring structure 302 may overlap. For example, and as shown in FIG. 4, the segmented metallization layer 306f (of the outer seal ring structure 306) may overlap with the segmented metallization layer 308g (of the inner seal ring structure 304) a distance D3. As an example, the distance D3 may be included in a range of approximately 10 μm to approximately 20 μm. However, other values and ranges for the distance D3 are within the scope of the present disclosure.

The trench capacitor structure 220f is electrically connected with the inner seal ring structure 304 through respective metallization layers 308g and 308h (e.g., respective electrically conductive traces). In some implementations, segmentation of the metallization layers 308g and 308h provides for a combination of discharge paths having different electrical characteristics (e.g., a discharge path corresponding to a positive polarity/Vdd (drain voltage) and/or another discharge path corresponding to a negative polarity/Vss (source voltage), among other examples).

An example configuration of the semiconductor die package 200, in the context of features described in FIG. 4 (and FIGS. 2A, 2B, and 3A-3C), includes a first IC die (e.g., the first semiconductor die 202). The first IC die includes a trench capacitor (e.g., the trench capacitor

structure 220f), a first seal ring segment (e.g., the metallization layer 304e), and a second seal ring segment (e.g., the metallization layer 304f) that is electrically isolated from the first seal ring segment. The semiconductor die package 200 includes a second IC die (e.g., the second semiconductor die 206) connected with the first integrated circuit die. The second IC die includes the PMIC 312 that includes a first voltage terminal (e.g., the negative polarity terminal 324) corresponding to a first polarity and a second voltage terminal (e.g., the positive polarity terminal 326) corresponding to a second polarity that is opposite the first polarity. The semiconductor die package 200 includes a first electrically conductive trace (e.g., the metallization layer 308f) connecting the trench capacitor, the first seal ring segment, and the first voltage terminal. The semiconductor die package 200 includes a second electrically conductive trace (e.g., the metallization layer 308g) connecting the trench capacitor, the second seal ring segment, and the second voltage terminal.

As indicated above, FIG. 4 is provided as an example. Other examples may differ from what is described with regard to FIG. 4.

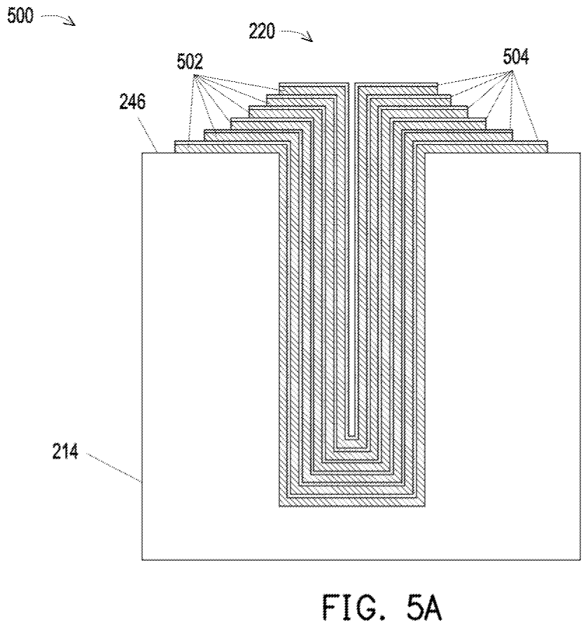

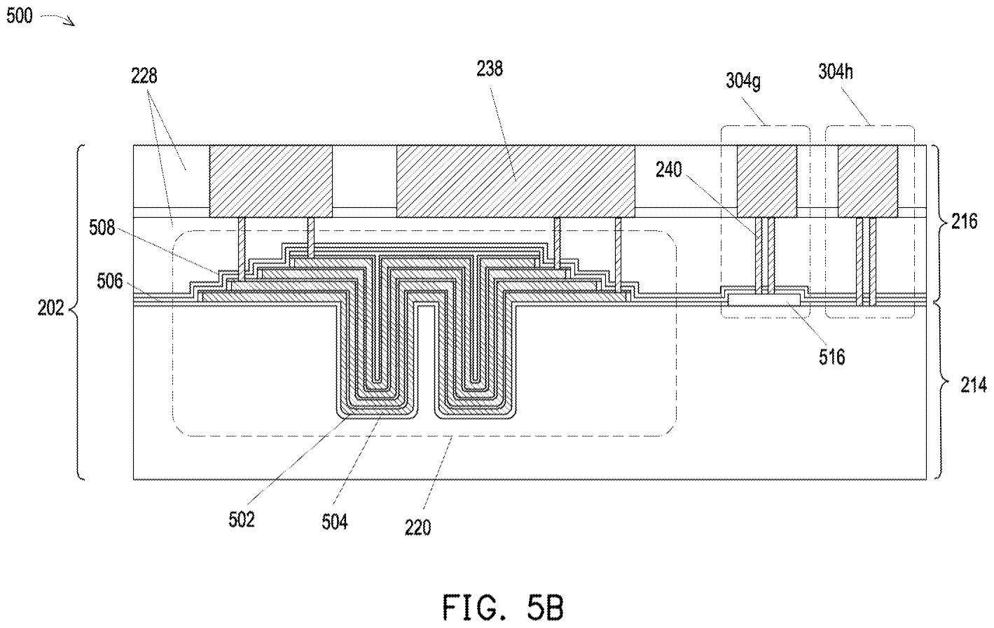

FIGS. 5A and 5B are diagrams of an example implementation 500 of a trench capacitor structure 220 described herein. As shown in FIG. 5A, the trench capacitor structure 220 may be formed in the device region 214. In particular, the trench capacitor structure 220 may extend into the semiconductor substrate of the device region 214 from the surface 246.

The trench capacitor structure 220 may include a plurality of conductive layers 502 and a plurality of dielectric layers 504. The conductive layers 502 and the dielectric layers 504 may be arranged in an alternating configuration in the trench capacitor structure 220. For example, a first conductive layer 502 may be included in the trench capacitor structure 220, a first dielectric layer 504 may be included over the first conductive layer 502, a second conductive layer 502 may be included over the first dielectric layer 504, and so on. A dielectric layer 504 between a pair of conductive layers 502 may correspond to a trench capacitor of the trench capacitor structure 220, where the conductive layers 502 correspond to the electrodes of the trench capacitor and the dielectric layer 504 corresponds to the dielectric medium of the trench capacitor. In this way, the trench capacitor structure 220 includes a plurality of layered trench capacitors that extend into the semiconductor substrate of the device region 214.

In general, a deeper trench capacitor structure 220 may provide a greater amount of decoupling capacitance relative to a shallower deeper trench capacitor structure 220. Additionally, and/or alternatively, a wider deeper trench capacitor structure 220 may include a greater quantity of conductive layers 502 and a greater quantity of dielectric layers 504 and, therefore, a greater quantity of trench capacitor s relative to a narrower deeper trench capacitor structure 220. This enables a wider deeper trench capacitor structure 220 to also provide a greater amount of decoupling capacitance relative to a narrower deeper trench capacitor structure 220.

The conductive layers 502 may include one or more conductive materials such as a conductive metal (e.g., copper (Cu), tungsten (W), titanium (Ti), tantalum (Ta), ruthenium (Ru), cobalt (Co)), a conductive ceramic (e.g., tantalum nitride (TaN), titanium nitride (TiN)), and/or another type of conductive material. The dielectric layers 504 may include one or more dielectric materials such as an oxide (e.g., silicon oxide (SiOₓ)), a nitride (e.g., silicon nitride (SiₓN_{y}), and/or another suitable dielectric material.

As further shown in FIG. 5A, the conductive layers 502 and the dielectric layers 504 may partially extend out of the semiconductor substrate of the device region 214 and may extend along a portion of the surface 246 of the semiconductor substrate of the device region 214. This enables conductive terminals to be electrically connected and/or physically connected with the conductive layers 502. The conductive terminals may electrically connect and/or physically connect the trench capacitor structure 220 to other structures and/or devices in the semiconductor die package 200.

FIG. 5B shows additional details of the example implementation 500 as part of an IC die (e.g., the first semiconductor die 202). As shown in FIG. 5B, the trench capacitor structure 220 includes the conductive layers 502 and the dielectric layers 504. Portions of the trench capacitor structure 220 (and/or the first semiconductor die 202) may include additional features, such as a liner layer 506 (e.g., a silicon nitride (SiN) layer, among other examples), an oxide layer 508, and or the dielectric layers 228. The first semiconductor die 202 may include the metallization layer 238 and/or one or more BTSV structures 240 connected to an electrode layer 516 (e.g., a titanium nitride (TiN) layer, among other examples) and/or one or more layers of the trench capacitor structure 220 (e.g., one or more of the conductive layers 502, among other examples).

In some implementations, the metallization layer 238 above the trench capacitor structure 220 includes a pattern of traces and/or electrical contacts (e.g., RDL structures) for routing electrical connections from the trench capacitor structure 220 (e.g., from the conductive layers 502) to circuitry and or electrical contacts external to the first semiconductor die 202. In some implementations, and as shown, the one or more BTSV structures 240 may be dispersed vertically between the metallization layer 238 and the conductive layers 502 (and/or the electrode layer 516). The metallization layers 238 may include one or more materials such as a gold (Au) material, a copper (Cu) material, a silver (Ag) material, a nickel (Ni) material, a tin (Sn) material, and/or a palladium (Pd) material, among other examples. The one or more BTSV structures 240 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

In some implementations, the first semiconductor die 202 includes a first portion of the inner seal ring structure (e.g., the metallization layer 304g, corresponding to a first segment of the inner seal ring structure 304) that is configured to connect to a V_{dd} terminal (a transistor drain voltage terminal). Additionally, or alternatively, a second portion of the inner seal ring structure (e.g., the metallization layer 304h, corresponding to a second segment of the inner seal ring structure 304) may be configured to connect to a Vₛₛ terminal (a transistor source voltage terminal).

As indicated above, FIGS. 5A and 5B are provided as an example. Other examples may differ from what is described with regard to FIGS. 5A and 5B.

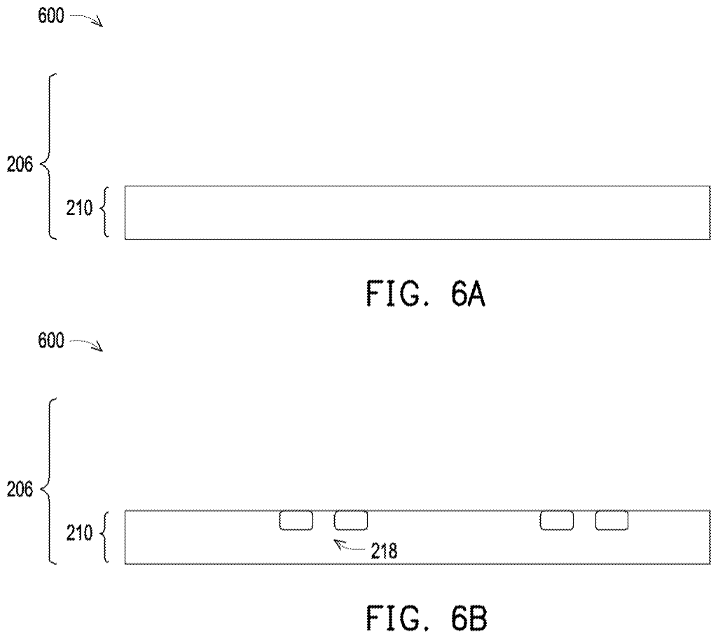

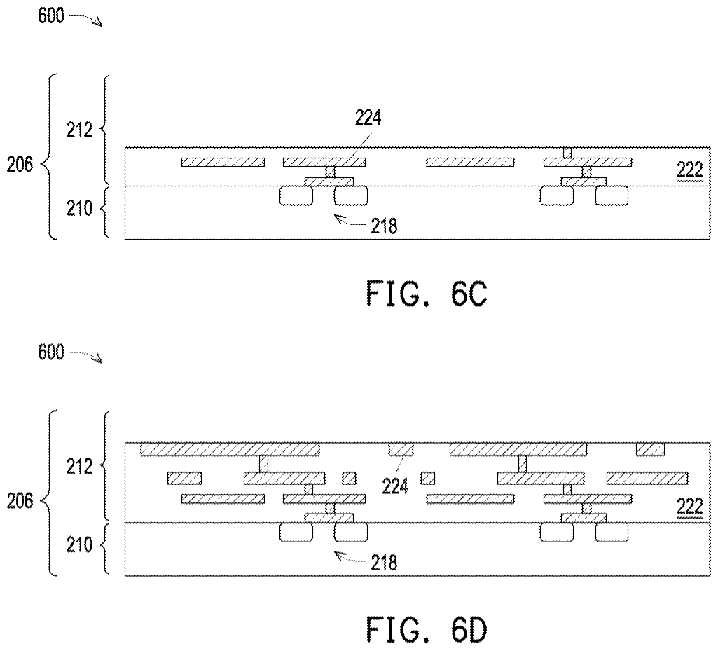

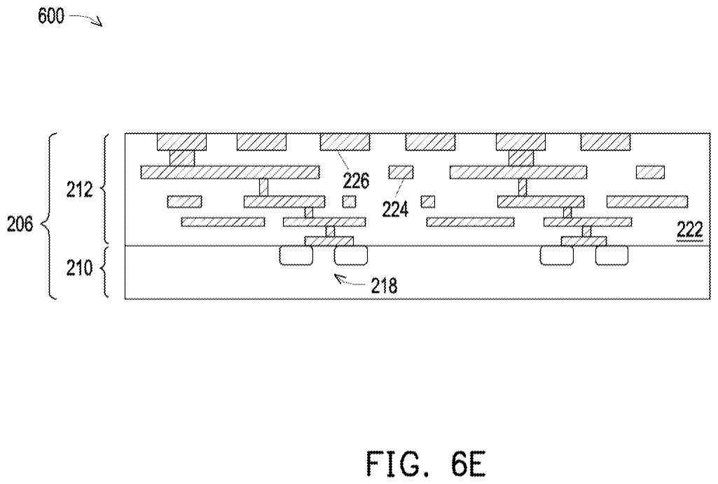

FIGS. 6A-6E are diagrams of an example implementation 600 of forming a semiconductor die described herein. In some implementations, the example implementation 600 includes an example process for forming a portion of the second semiconductor die 206. In some implementations, one or more of the semiconductor processing tools 102-114 and/or the wafer/die transport tool 116 may perform one or more of the operations described in connection with the example implementation 600. In some implementations, one or more operations described in connection with the example implementation 600 may be performed by another semiconductor processing tool.

Turning to FIG. 6A, one or more of the operations in the example implementation 600 may be performed in connection with the semiconductor substrate of the device region 210 of the second semiconductor die 206. The semiconductor substrate of the device region 210 may be provided in the form of a semiconductor wafer or another type of substrate.

As shown in FIG. 6B, one or more semiconductor devices 218 may be formed in the device region 210. For example, one or more of the semiconductor processing tools 102-114 may perform photolithography patterning operations, etching operations, deposition operations, CMP operations, and/or another type of operations to form one or more transistors, one or more capacitors, one or more memory cells, one or more circuits (e.g., one or more ICs), and/or one or more semiconductor devices of another type. In some implementations, one or more regions of the semiconductor substrate of the device region 210 may be doped in an ion implantation operation to form one or more p-wells, one or more n-wells, and/or one or more deep n-wells. In some implementations, the deposition tool 102 may deposit one or more source/drain regions, one or more gate structures, and/or one or more STI regions, among other examples.

As shown in FIGS. 6C-6E, the interconnect region 212 of the second semiconductor die 206 may be formed over and/or on the semiconductor substrate of the device region 210. One or more of the semiconductor processing tools 102-114 may form the interconnect region 212 by forming one or more dielectric layers 222 and forming a plurality of metallization layers 224 in the plurality of dielectric layers 222. For example, the deposition tool 102 may deposit a first layer of the one or more dielectric layers 222 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 224 in the recesses (e.g., using a CVD technique, an ALD technique, a PVD technique, an electroplating technique, and/or another type of deposition technique). At least a portion of the first metallization layer may be electrically connected and/or physically connected with the semiconductor device(s) 218. The deposition tool 102, the etch tool 108, the plating tool 112, and/or another semiconductor processing tool may continue to perform similar processing operations to forming the interconnect region 212 until a sufficient or desired arrangement of metallization layers 224 is achieved.

As shown in FIG. 6E, one or more of the semiconductor processing tools 102-114 may form another layer of the one or more dielectric layers 222, and may form a plurality of contacts 226 in the layer such that the contacts 226 are electrically connected and/or physically connected with one or more of the metallization layers 224. For example, the deposition tool 102 may deposit the layer of the one or more dielectric layers 222 (e.g., using a CVD technique, an ALD technique, a PVD technique, and/or another type of deposition technique), the etch tool 108 may remove portions of the layer to form recesses in the layer, and the deposition tool 102 and/or the plating tool 112 may form the contacts 226 in the recesses (e.g., using a CVD technique, an ALD technique, a PVD technique, an electroplating technique, and/or another type of deposition technique).

As indicated above, FIGS. 6A-6E are provided as an example. Other examples may differ from what is described with regard to FIGS. 6A-6E.

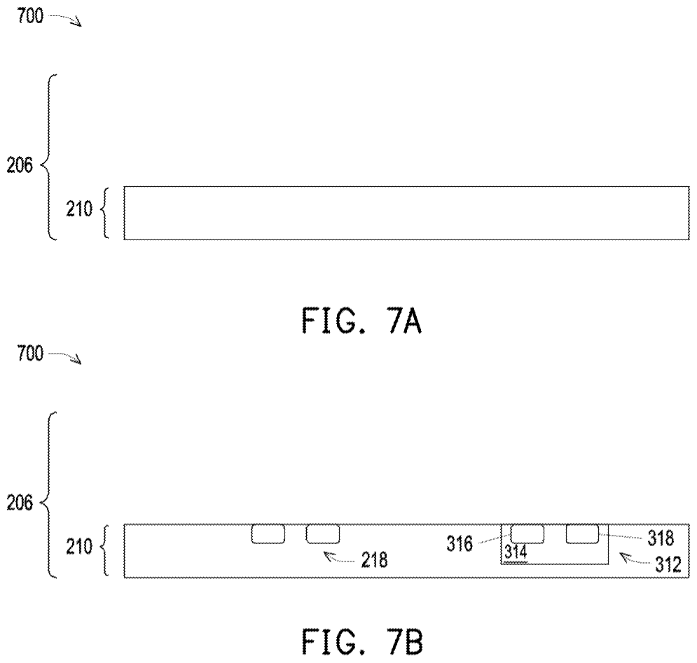

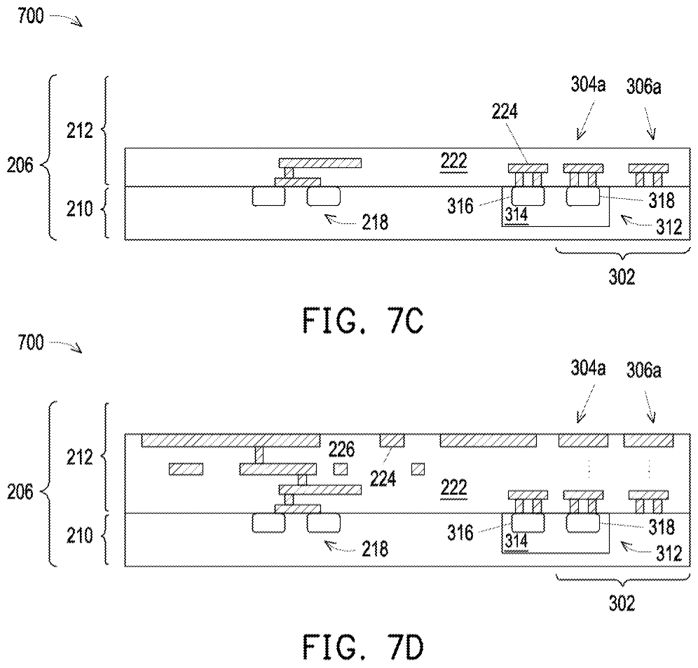

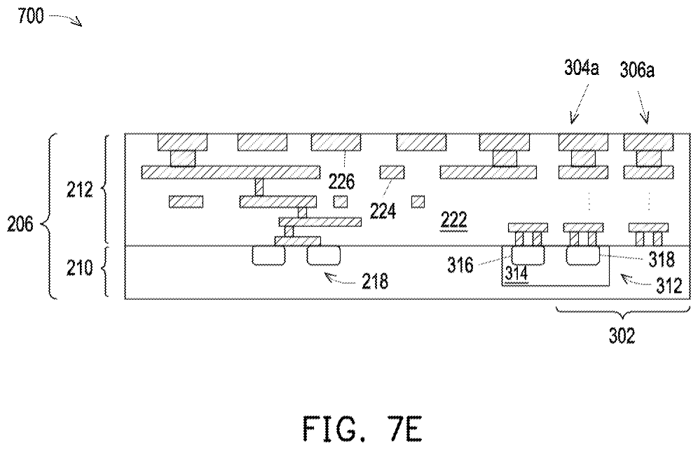

FIGS. 7A-7E are diagrams of an example implementation 700 of forming a semiconductor die described herein. In some implementations, the example implementation 700 includes an example process for forming another portion the second semiconductor die 206. In some implementations, one or more of the semiconductor processing tools 102-114 and/or the wafer/die transport tool 116 may perform one or more of the operations described in connection with the example implementation 700. In some implementations, one or more operations described in connection with the example implementation 700 may be performed by another semiconductor processing tool.

Turning to FIG. 7A, one or more of the operations in the example implementation 700 may be performed in connection with the semiconductor substrate of the device region 210 of the second semiconductor die 206. The semiconductor substrate of the device region 210 may be provided in the form of a semiconductor wafer or another type of substrate.

As shown in FIG. 7B, one or more semiconductor devices 218 may be formed in the device region 210. For example, one or more of the semiconductor processing tools 102-114 may perform photolithography patterning operations, etching operations, deposition operations, CMP operations, and/or another type of operations to form one or more transistors, one or more capacitors, one or more memory cells, one or more circuits (e.g., one or more ICs), and/or one or more semiconductor devices of another type. In some implementations, one or more regions of the semiconductor substrate of the device region 210 may be doped in an ion implantation operation to form one or more p-wells, one or more n-wells, and/or one or more deep n-wells. In some implementations, the deposition tool 102 may deposit one or more source/drain regions, one or more gate structures, and/or one or more STI regions, among other examples.

As further shown in FIG. 7B, an PMIC 312 may be formed in the semiconductor substrate of the device region 210. In some implementations, one or more regions of the semiconductor substrate of the device region 210 may be doped in an ion implantation operation to form an n-well 314. In some implementations, one or more of the semiconductor processing tools 102-114 may perform photolithography patterning operations, etching operations, deposition operations, CMP operations, and/or another type of operations to form an n-type contact 316 of a diode of the PMIC 312 and a p-type contact 318 of the diode of the PMIC 312.

As shown in FIGS. 7C-7E, the interconnect region 212 of the second semiconductor die 206 may be formed over and/or on the semiconductor substrate of the device region 210. One or more of the semiconductor processing tools 102-114 may form the interconnect region 212 by forming one or more dielectric layers 222 and forming a plurality of metallization layers 224 in the plurality of dielectric layers 222. For example, the deposition tool 102 may deposit a first layer of the one or more dielectric layers 222 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 224 in the recesses (e.g., using a CVD technique, an ALD technique, a PVD technique, an electroplating technique, and/or another type of deposition technique). At least a portion of the first metallization layer may be electrically connected and/or physically connected with the semiconductor device(s) 218. Another portion of the first metallization layer may be electrically connected and/or physically connected with one or more n-type contacts 316 of the PMIC 312. The deposition tool 102, the etch tool 108, the plating tool 112, and/or another semiconductor processing tool may continue to perform similar processing operations to forming the interconnect region 212 until a sufficient or desired arrangement of metallization layers 224 is achieved.

As further shown in FIG. 7C-7E, a plurality of structures may be formed in a portion 302a of a seal ring structure 302 in the interconnect region 212. For example, a portion (e.g. the metallization layer 304a) of an inner seal ring structure 304 of the seal ring structure 302 may be formed in the interconnect region 212. As another example, a portion (e.g., the metallization layer 306a) of an outer seal ring structure 306 of the seal ring structure 302 may be formed in the interconnect region 212. Forming the portions may include forming a plurality of metallization layers 224 in the one or more dielectric layers 222 of the interconnect region 212. For example, the deposition tool 102 may deposit a first layer of the one or more dielectric layers 222 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 224 in the recesses (e.g., using a CVD technique, an ALD technique, a PVD technique, an electroplating technique, and/or another type of deposition technique) for the portion 302a of the seal ring structure 302. At least a portion of the first metallization layer may be electrically connected and/or physically connected with one or more p-type contacts 318 of the PMIC 312. The deposition tool 102, the etch tool 108, the plating tool 112, and/or another semiconductor processing tool may continue to perform similar processing operations to forming the interconnect region 212 until a sufficient or desired arrangement of metallization layers 224 in the portion 302a of the seal ring structure 302 is achieved.

As shown in FIG. 7E, one or more of the semiconductor processing tools 102-114 may form another layer of the one or more dielectric layers 222, and may form a plurality of contacts 226 in the layer such that the contacts 226 are electrically connected and/or physically connected with one or more of the metallization layers 224. For example, the deposition tool 102 may deposit the layer of the one or more dielectric layers 222 (e.g., using a CVD technique, an ALD technique, a PVD technique, and/or another type of deposition technique), the etch tool 108 may remove portions of the layer to form recesses in the layer, and the deposition tool 102 and/or the plating tool 112 may form the contacts 226 in the recesses (e.g., using a CVD technique, an ALD technique, a PVD technique, an electroplating technique, and/or another type of deposition technique).

As indicated above, FIGS. 7A-7E are provided as an example. Other examples may differ from what is described with regard to FIGS. 7A-7E.

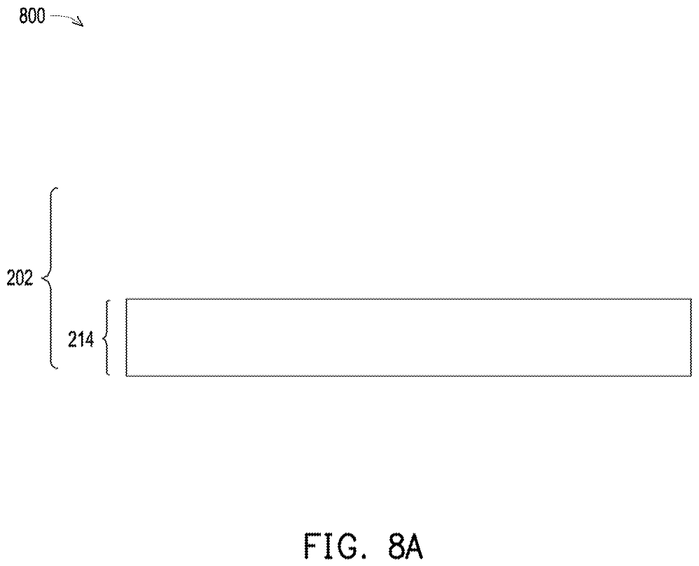

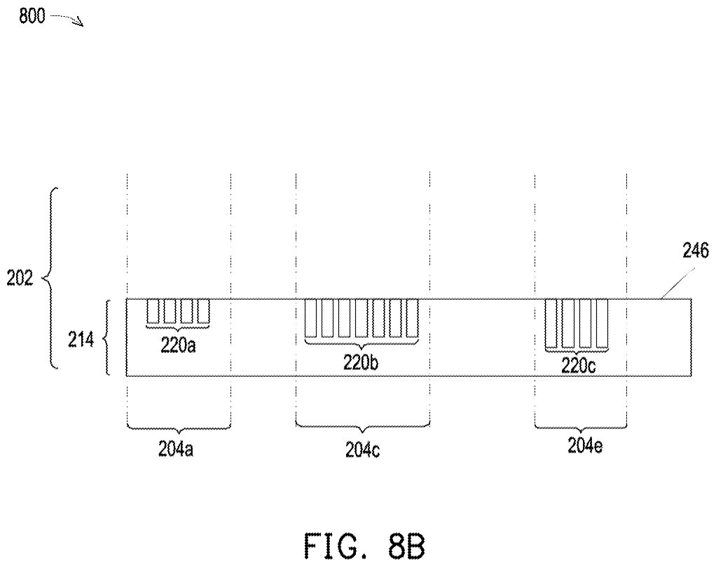

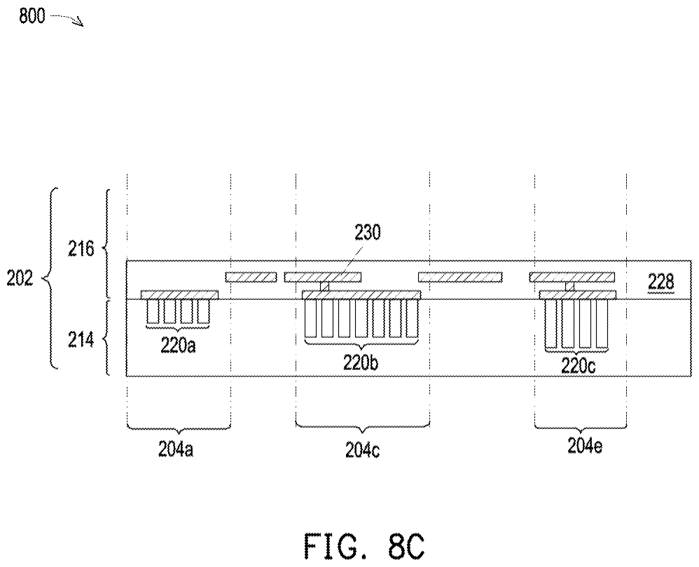

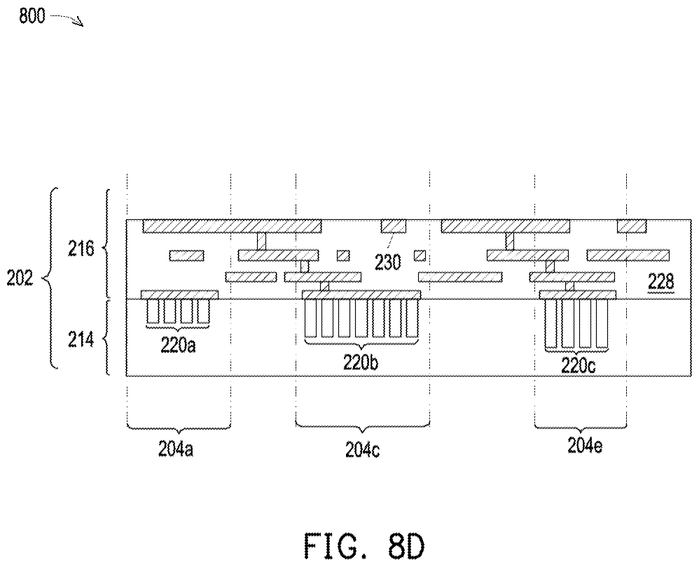

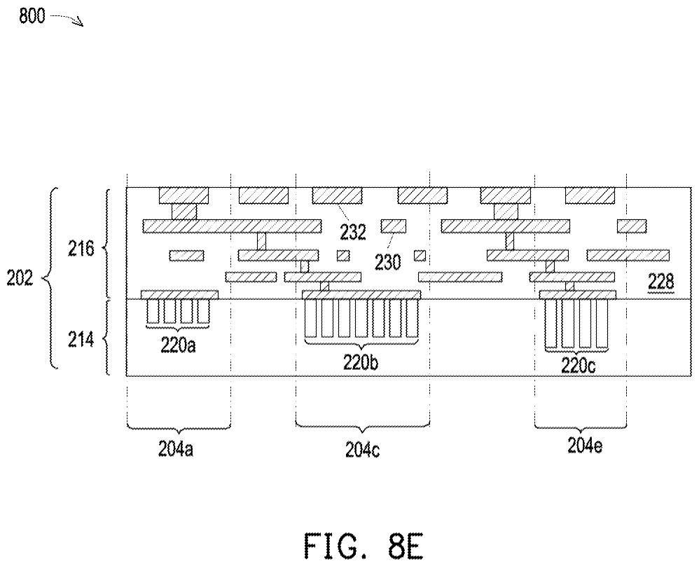

FIGS. 8A-8E are diagrams of an example implementation 800 of forming a semiconductor die described herein. In some implementations, the example implementation 800 includes an example process for forming a portion of the first semiconductor die 202. In some implementations, one or more of the semiconductor processing tools 102-114 and/or the wafer/die transport tool 116 may perform one or more of the operations described in connection with the example implementation 800. In some implementations, one or more operations described in connection with the example implementation 800 may be performed by another semiconductor processing tool.

Turning to FIG. 8A, one or more of the operations in the example implementation 800 may be performed in connection with the semiconductor substrate of the device region 214 of the first semiconductor die 202. The semiconductor substrate of the device region 214 may be provided in the form of a semiconductor wafer or another type of substrate.

As shown in FIG. 8B, a plurality of trench capacitor structures may be formed in the device region 214. In particular, respective pluralities of trench capacitor structures may be formed in each of a plurality of trench capacitor regions in the device region 214.

As an example of the above, one or more of the semiconductor processing tools 102-114 may perform photolithography patterning operations, etching operations, deposition operations, CMP operations, and/or another type of operations to form a trench capacitor structure 220a in a trench capacitor region 204a of the device region 214, a trench capacitor structure 220b in a trench capacitor region 204c of the device region 214, and a trench capacitor structure 220c in a trench capacitor region 204e of the device region 214.

To form a trench capacitor structure, a recess may be formed in the semiconductor substrate (e.g., from the surface 246) of the device region 214 using a pattern in a photoresist layer, a hard mask, and/or another type of masking layer. For example, the deposition tool 102 forms a photoresist layer over the semiconductor substrate of the device region 214. The exposure tool 104 exposes the photoresist layer to a radiation source to pattern the photoresist layer. The developer tool 106 develops and removes portions of the photoresist layer to expose the pattern. The etch tool 108 etches into the semiconductor substrate of the device region 214 to form the recess. The deposition tool 102 may perform a deposition operation (e.g., a CVD operation, a PVD operation, an ALD operation) to deposit a first conductive layer 502 in the recess such that the first conductive layer 502 conforms to the shape of the recess. The deposition tool 102 may perform a deposition operation (e.g., a CVD operation, a PVD operation, an ALD operation) to deposit a first dielectric layer 504 on the first conductive layer 502. The deposition tool 102 may perform a deposition operation (e.g., a CVD operation, a PVD operation, an ALD operation) to deposit a second conductive layer 502 on the first dielectric layer 504. The deposition tool 102 may perform a deposition operation (e.g., a CVD operation, a PVD operation, an ALD operation) to deposit a second dielectric layer 504 on the second conductive layer 502. The deposition tool 102 may perform subsequent deposition operations until a sufficient or desired quantity of deep trench capacitors are formed in the recess for the deep trench capacitor structure.

As shown in FIGS. 8C-8E, the interconnect region 216 of the first semiconductor die 202 may be formed over and/or on the semiconductor substrate of the device region 214. One or more of the semiconductor processing tools 102-114 may form the interconnect region 216 by forming one or more dielectric layers 228 and forming a plurality of metallization layers 230 in the plurality of dielectric layers 228. For example, the deposition tool 102 may deposit a first layer of the one or more dielectric layers 228 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 230 in the recesses (e.g., using a CVD technique, an ALD technique, a PVD technique, an electroplating technique, and/or another type of deposition technique). The deposition tool 102, the etch tool 108, the plating tool 112, and/or another semiconductor processing tool may continue to perform similar processing operations to forming the interconnect region 216 until a sufficient or desired arrangement of metallization layers 230 is achieved.

The trench capacitor structure 220a in the trench capacitor region 204a may be electrically connected and/or physically connected with one or more of the metallization layers 230. The trench capacitor structure 220b in the trench capacitor region 204c may be electrically connected and/or physically connected with one or more of the metallization layers 230. The trench capacitor structure 220c in the trench capacitor region 204e may be electrically connected and/or physically connected with one or more of the metallization layers 230.

As shown in FIG. 8E, one or more of the semiconductor processing tools 102-114 may form another layer of the one or more dielectric layers 228, and may form a plurality of contacts 232 in the layer such that the contacts 232 are electrically connected and/or physically connected with one or more of the metallization layers 230. For example, the deposition tool 102 may deposit the layer of the one or more dielectric layers 228 (e.g., using a CVD technique, an ALD technique, a PVD technique, and/or another type of deposition technique), the etch tool 108 may remove portions of the layer to form recesses in the layer, and the deposition tool 102 and/or the plating tool 112 may form the contacts 232 in the recesses (e.g., using a CVD technique, an ALD technique, a PVD technique, an electroplating technique, and/or another type of deposition technique).

As indicated above, FIGS. 8A-8E are provided as an example. Other examples may differ from what is described with regard to FIGS. 8A-8E.

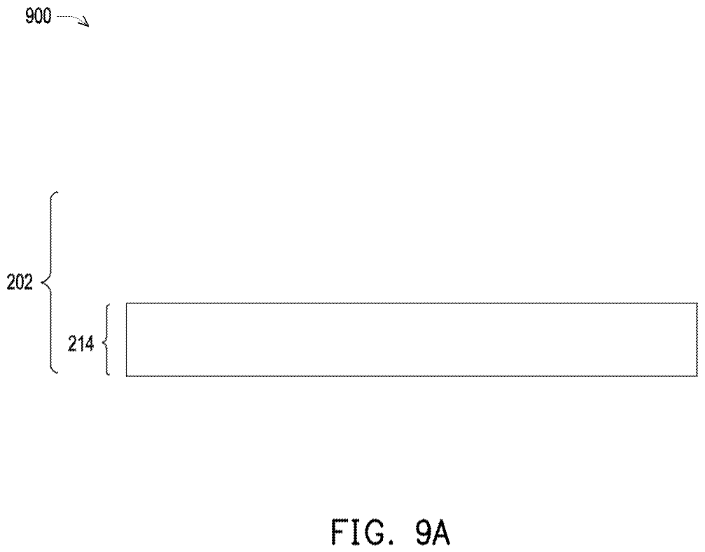

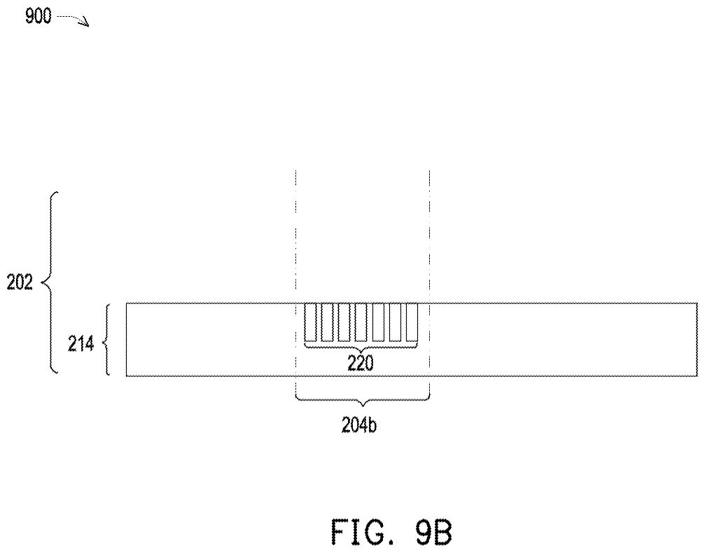

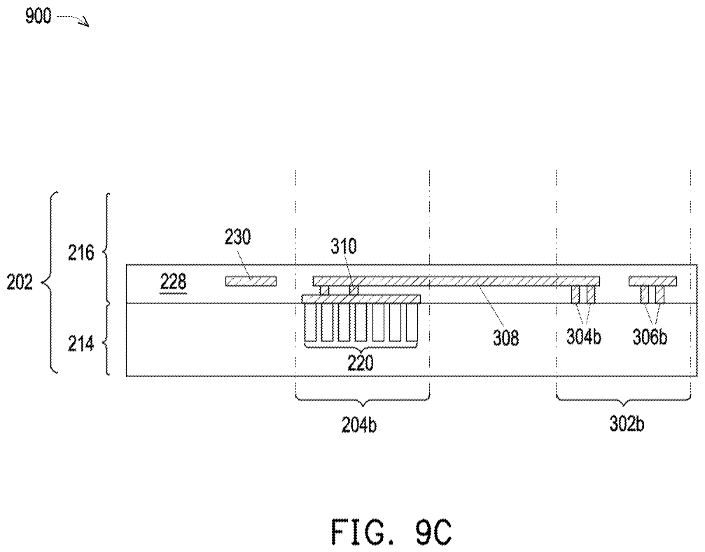

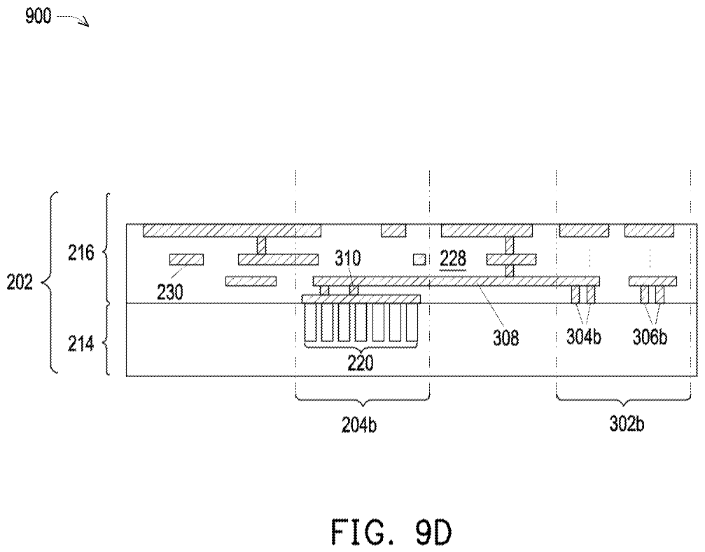

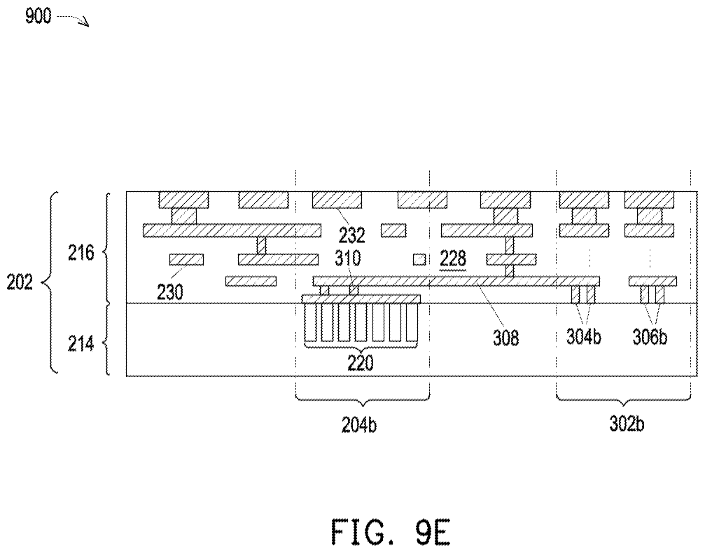

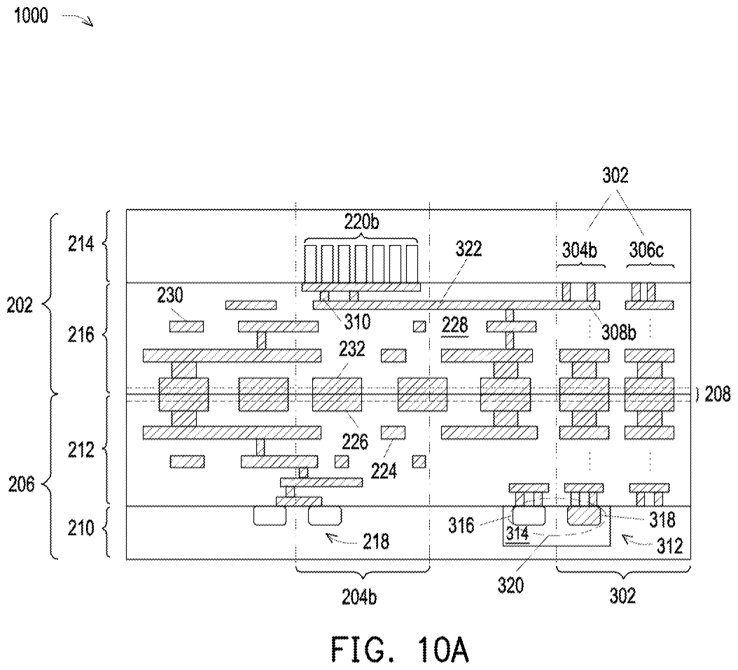

FIGS. 9A-9E are diagrams of an example implementation 900 of forming a semiconductor die described herein. In some implementations, the example implementation 900 includes an example process for forming another portion the first semiconductor die 202. In some implementations, one or more of the semiconductor processing tools 102-114 and/or the wafer/die transport tool 116 may perform one or more of the operations described in connection with the example implementation 900. In some implementations, one or more operations described in connection with the example implementation 900 may be performed by another semiconductor processing tool.

Turning to FIG. 9A, one or more of the operations in the example implementation 900 may be performed in connection with the semiconductor substrate of the device region 214 of the first semiconductor die 202. The semiconductor substrate of the device region 214 may be provided in the form of a semiconductor wafer or another type of substrate.

As shown in FIG. 9B, a plurality of trench capacitor structure 220 may be formed in a trench capacitor region 204b of the device region 214. To form a trench capacitor structure, a recess may be formed in the semiconductor substrate of the device region 214 using a pattern in a photoresist layer, a hard mask, and/or another type of masking layer. For example, the deposition tool 102 forms a photoresist layer over the semiconductor substrate of the device region 214. The exposure tool 104 exposes the photoresist layer to a radiation source to pattern the photoresist layer. The developer tool 106 develops and removes portions of the photoresist layer to expose the pattern. The etch tool 108 etches into the semiconductor substrate of the device region 214 to form the recess. The deposition tool 102 may perform a deposition operation (e.g., a CVD operation, a PVD operation, an ALD operation) to deposit a first conductive layer 502 in the recess such that the first conductive layer 502 conforms to the shape of the recess. The deposition tool 102 may perform a deposition operation (e.g., a CVD operation, a PVD operation, an ALD operation) to deposit a first dielectric layer 504 on the first conductive layer 502. The deposition tool 102 may perform a deposition operation (e.g., a CVD operation, a PVD operation, an ALD operation) to deposit a second conductive layer 502 on the first dielectric layer 504. The deposition tool 102 may perform a deposition operation (e.g., a CVD operation, a PVD operation, an ALD operation) to deposit a second dielectric layer 504 on the second conductive layer 502. The deposition tool 102 may perform subsequent deposition operations until a sufficient or desired quantity of deep trench capacitors are formed in the recess for the deep trench capacitor structure.

As shown in FIGS. 9C-9E, the interconnect region 216 of the first semiconductor die 202 may be formed over and/or on the semiconductor substrate of the device region 214. One or more of the semiconductor processing tools 102-114 may form the interconnect region 216 by forming one or more dielectric layers 228 and forming a plurality of metallization layers 230 in the plurality of dielectric layers 228. For example, the deposition tool 102 may deposit a first layer of the one or more dielectric layers 228 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 230 in the recesses (e.g., using a CVD technique, an ALD technique, a PVD technique, an electroplating technique, and/or another type of deposition technique). At least a portion of the first metallization layer may be electrically connected and/or physically connected with the trench capacitor structure 220. The deposition tool 102, the etch tool 108, the plating tool 112, and/or another semiconductor processing tool may continue to perform similar processing operations to forming the interconnect region 212 until a sufficient or desired arrangement of metallization layers 230 is achieved.

As further shown in FIG. 9C-9E, a plurality of structures may be formed in a portion 302b of a seal ring structure 302 in the interconnect region 216. For example, a portion (e.g., the metallization layer 304a) of an inner seal ring structure 304 of the seal ring structure 302 may be formed in the interconnect region 212. As another example, a portion (e.g., the metallization layer 306b) of an outer seal ring structure 306 of the seal ring structure 302 may be formed in the interconnect region 212. Forming the portions may include forming a plurality of metallization layers 230 in the one or more dielectric layers 228 of the interconnect region 216. For example, the deposition tool 102 may deposit a first layer of the one or more dielectric layers 228 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 230 in the recesses (e.g., using a CVD technique, an ALD technique, a PVD technique, an electroplating technique, and/or another type of deposition technique) in the portion 302b of the seal ring structure 302. The deposition tool 102, the etch tool 108, the plating tool 112, and/or another semiconductor processing tool may continue to perform similar processing operations to forming the interconnect region 216 until a sufficient or desired arrangement of metallization layers 230 in the portion 302b of the seal ring structure 302 is achieved.

As further shown in FIGS. 9C-9E, conductive lines 310 and the metallization layers 308 may be formed in the one or more dielectric layers 228. The conductive lines 310 and metallization layers 308 may electrically connect and/or physically connect the trench capacitor structure 220 in the trench capacitor region 204b with the portion 302b of the seal ring structure 302. In particular, the conductive lines 310 and the metallization layers 308 may electrically connect and/or physically connect the trench capacitor structure 220 in the trench capacitor region 204b with the portion 302b of the inner seal ring structure 304 of the seal ring structure 302.

As shown in FIG. 9E, one or more of the semiconductor processing tools 102-114 may form another layer of the one or more dielectric layers 228, and may form a plurality of contacts 232 in the layer such that the contacts 232 are electrically connected and/or physically connected with one or more of the metallization layers 230. For example, the deposition tool 102 may deposit the layer of the one or more dielectric layers 228 (e.g., using a CVD technique, an ALD technique, a PVD technique, and/or another type of deposition technique), the etch tool 108 may remove portions of the layer to form recesses in the layer, and the deposition tool 102 and/or the plating tool 112 may form the contacts 232 in the recesses (e.g., using a CVD technique, an ALD technique, a PVD technique, an electroplating technique, and/or another type of deposition technique).

As indicated above, FIGS. 9A-9E are provided as an example. Other examples may differ from what is described with regard to FIGS. 9A-9E.

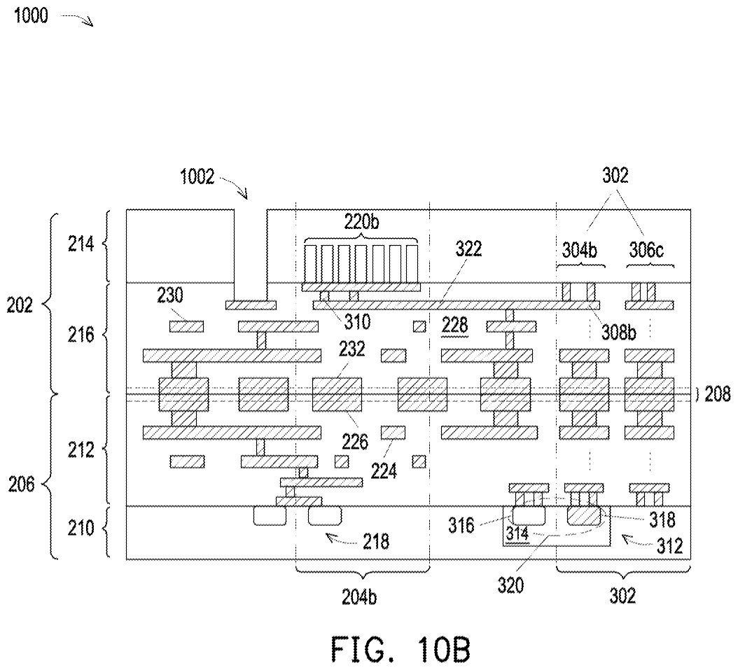

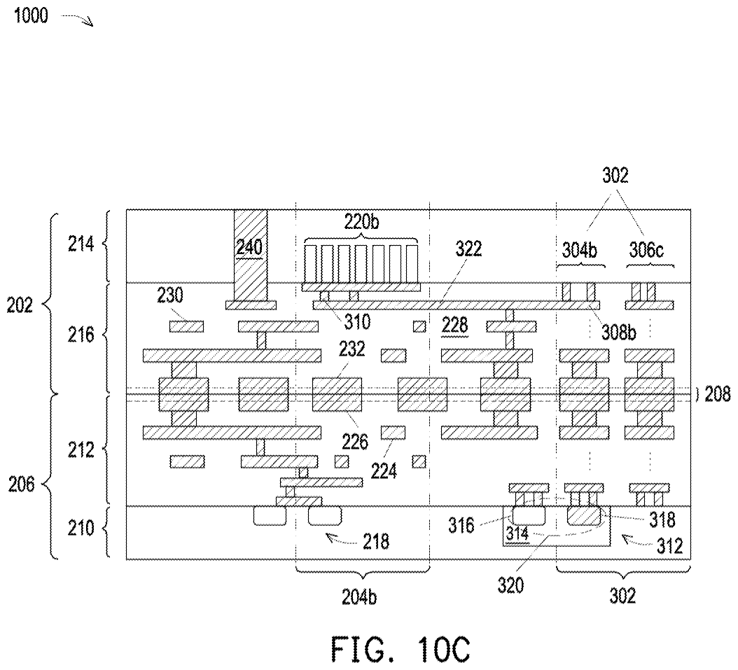

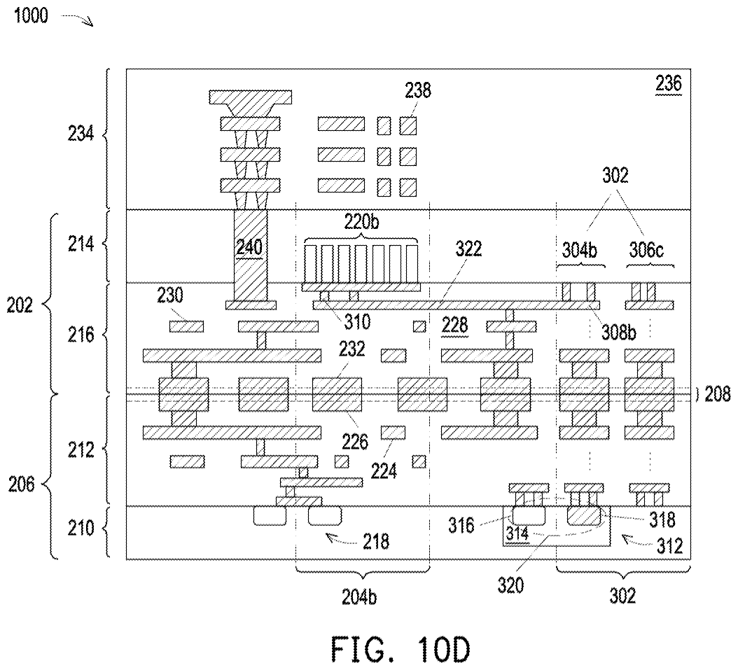

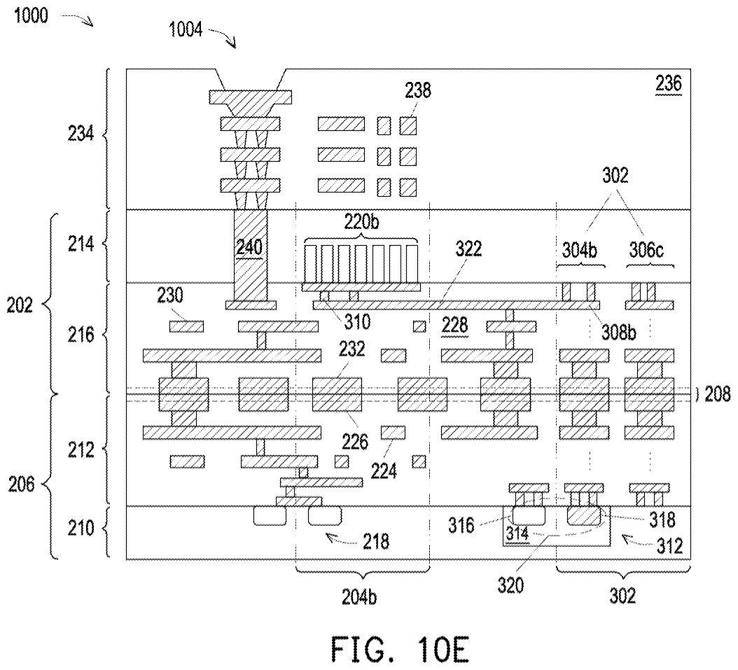

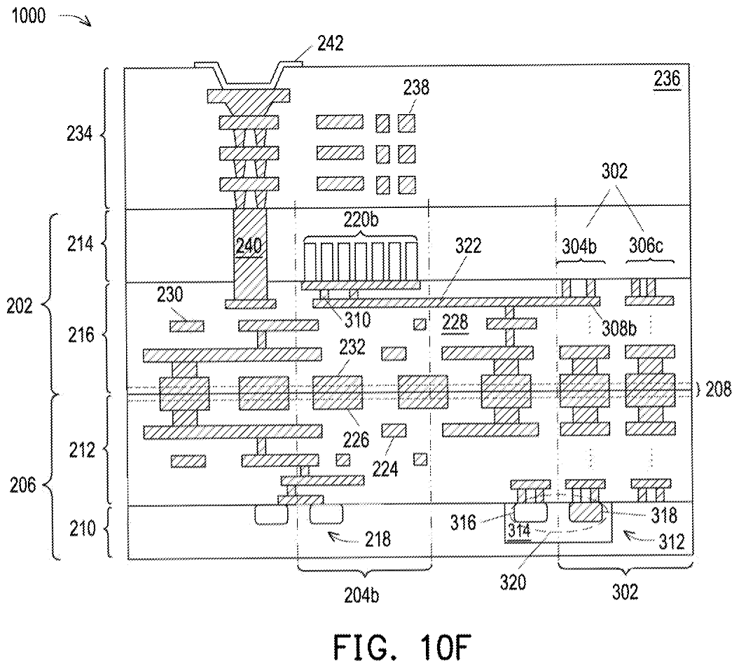

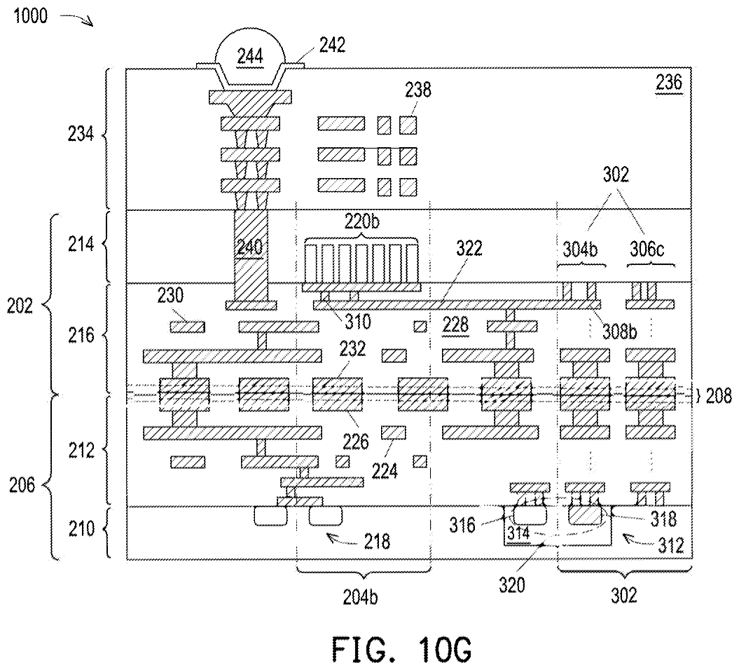

FIGS. 10A-10G are diagrams of an example implementation 1000 of forming a portion of a semiconductor die package 200 described herein. In some implementations, one or more operations described in connection with FIGS. 10A-10G may be performed by one or more of the semiconductor processing tools 102-114 and/or the wafer/die transport tool 116. In some implementations, one or more operations described in connection with FIGS. 10A-10G may be performed by another semiconductor processing tool.

As shown in FIG. 10A, the first semiconductor die 202 and the second semiconductor die 206 may be bonded at the bonding interface 208 such that the first semiconductor die 202 and the second semiconductor die 206 are vertically arranged or stacked. The first semiconductor die 202 and the second semiconductor die 206 may be vertically arranged or stacked in a WoW configuration, a die on wafer configuration, a die on die configuration, and/or another direct bonding configuration. The bonding tool 114 may perform a bonding operation to bond the first semiconductor die 202 and the second semiconductor die 206 at the bonding interface 208. The bonding operation may include a direct bonding operation in which bonding of first semiconductor die 202 and the second semiconductor die 206 is achieved through the physical connection of the contacts 226 with the contacts 232. At the bonding interface 208, a direct metal bonding is formed between the contacts 226/232, and a direct dielectric bond is formed between two dielectric layers.

As shown in FIG. 10B, one or more recesses 1002 may be formed through the semiconductor substrate of the device region 214 and into a portion of the dielectric layer 228 of the interconnect region 216. The one or more recesses 1002 may be formed to expose one or more portions of a metallization layer 230 in the interconnection region 216. Thus, the one or more recesses 1002 may be formed over the one or more portions of a metallization layer 230.

In some implementations, a pattern in a photoresist layer is used to form the one or more recesses 1002. In these implementations, the deposition tool 102 forms the photoresist layer over the silicon substrate of the device region 214. The exposure tool 104 exposes the photoresist layer to a radiation source to pattern the photoresist layer. The developer tool 106 develops and removes portions of the photoresist layer to expose the pattern. The etch tool 108 etches through the semiconductor substrate of the device region 214 and into a portion of the dielectric layer 228 of the interconnect region 216 to form the one or more recesses 1002. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the one or more recesses 1002 based on a pattern.

As shown in FIG. 10C, one or more BTSV structures 240 may be formed in the one or more recesses 1002. In this way, the one or more BTSV structures 240 extend through the semiconductor substrate the device region 214 and into the interconnect region 216. The one or more BTSV structures 240 may be electrically connected and/or physically connected with the one or more portions of the metallization layer 230 that were exposed through the one or more recesses 1002.

The deposition tool 102 and/or the plating tool 112 may deposit the one or more BTSV structures 240 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the one or more BTSV structures 240 after the one or more BTSV structures 240 are deposited.

As shown in FIG. 10D, the redistribution structure 234 of the semiconductor die package 200 may be formed over the first semiconductor die 202. One or more of the semiconductor processing tools 102-114 may form the redistribution structure 234 by forming one or more dielectric layers 236 and forming a plurality of metallization layers 238 in the plurality of dielectric layers 236. For example, the deposition tool 102 may deposit a first layer of the one or more dielectric layers 236 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 238 in the recesses (e.g., using a CVD technique, an ALD technique, a PVD technique, an electroplating technique, and/or another type of deposition technique). At least a portion of the first metallization layer may be electrically connected and/or physically connected with the one or more BTSV structures 240. The deposition tool 102, the etch tool 108, the plating tool 112, and/or another semiconductor processing tool may continue to perform similar processing operations to forming the redistribution structure 234 until a sufficient or desired arrangement of metallization layers 238 is achieved.

As shown in FIG. 10E, recesses 1004 may be formed in the one or more dielectric layers 236. The recesses 1004 may be formed to expose portions of a metallization layer 238 in the redistribution structure 234. Thus, the recesses 1004 may be formed over the one or more portions of a metallization layer 238.

In some implementations, a pattern in a photoresist layer is used to form the recesses 1002. In these implementations, the deposition tool 102 forms the photoresist layer on the one or more dielectric layers 236. The exposure tool 104 exposes the photoresist layer to a radiation source to pattern the photoresist layer. The developer tool 106 develops and removes portions of the photoresist layer to expose the pattern. The etch tool 108 etches into the one or more dielectric layers 236 to form the recesses 1002. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 1004 based on a pattern.

As shown in FIG. 10F, UBM layers 242 may be formed in the recesses 1004. The deposition tool 102 and/or the plating tool 112 may deposit the UBM layers 242 using a CVD technique, a PVD technique, an ALD technique, an electroplating technique, another deposition technique described above in connection with FIG. 1, and/or a deposition technique other than as described above in connection with FIG. 1. In some implementations, a continuous layer of conductive material is deposited on the top surface of the redistribution structure 234, including in the recess 1002. The continuous layer of conductive material is then patterned (e.g., by the deposition tool 102, the exposure tool 104, and the developer tool 106) to form a pattern on the continuous layer of the conductive material, and the etch tool 108 removes portions of the continuous layer of the conductive material based on the pattern. Remaining portions of the continuous layer of the conductive material may correspond to the UBM layers 242.

As shown in FIG. 10G, conductive terminals 244 may be formed in the recesses 1004 over the UBM layers 242. In some implementations, the plating tool 112 forms the conductive terminals 244 using an electroplating technique. In some implementations, solder is dispensed in the recesses 1004 to form the conductive terminals 244.

As indicated above, FIGS. 10A-10G are provided as an example. Other examples may differ from what is described with regard to FIGS. 10A-10G.

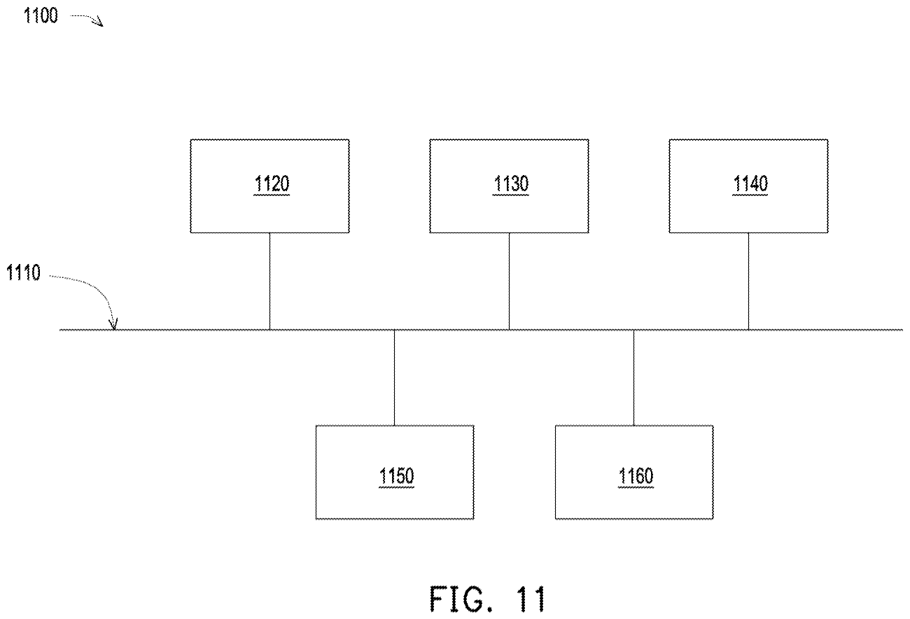

FIG. 11 is a diagram of example components of a device 1100 described herein. In some implementations, one or more of the semiconductor processing tools 102-114 and/or the wafer/die transport tool 116 may include one or more devices 1100 and/or one or more components of the device 1100. As shown in FIG. 10, the device 1100 may include a bus 1110, a processor 1120, a memory 1130, an input component 1140, an output component 1150, and/or a communication component 1160.

The bus 1110 may include one or more components that enable wired and/or wireless communication among the components of the device 1100. The bus 1110 may couple together two or more components of FIG. 10, such as via operative coupling, communicative coupling, electronic coupling, and/or electric coupling. For example, the bus 1110 may include an electrical connection, a wire, a trace, a lead, and/or a wireless bus. The processor 1120 may include a central processing unit, a graphics processing unit, a microprocessor, a controller, a microcontroller, a digital signal processor, a field-programmable gate array, an application-specific integrated circuit, and/or another type of processing component. The processor 1120 may be implemented in hardware, firmware, or a combination of hardware and software. In some implementations, the processor 1120 may include one or more processors capable of being programmed to perform one or more operations or processes described elsewhere herein.

The memory 1130 may include volatile and/or nonvolatile memory. For example, the memory 1130 may include random access memory (RAM), read only memory (ROM), a hard disk drive, and/or another type of memory (e.g., a flash memory, a magnetic memory, and/or an optical memory). The memory 1130 may include internal memory (e.g., RAM, ROM, or a hard disk drive) and/or removable memory (e.g., removable via a universal serial bus connection). The memory 1130 may be a non-transitory computer-readable medium. The memory 1130 may store information, one or more instructions, and/or software (e.g., one or more software applications) related to the operation of the device 1100. In some implementations, the memory 1130 may include one or more memories that are coupled (e.g., communicatively coupled) to one or more processors (e.g., processor 1120), such as via the bus 1110. Communicative coupling between a processor 1120 and a memory 1130 may enable the processor 1120 to read and/or process information stored in the memory 1130 and/or to store information in the memory 1130.

The input component 1140 may enable the device 1100 to receive input, such as user input and/or sensed input. For example, the input component 1140 may include a touch screen, a keyboard, a keypad, a mouse, a button, a microphone, a switch, a sensor, a global positioning system sensor, an accelerometer, a gyroscope, and/or an actuator. The output component 1150 may enable the device 1100 to provide output, such as via a display, a speaker, and/or a light-emitting diode. The communication component 1160 may enable the device 1100 to communicate with other devices via a wired connection and/or a wireless connection. For example, the communication component 1160 may include a receiver, a transmitter, a transceiver, a modem, a network interface card, and/or an antenna.

The device 1100 may perform one or more operations or processes described herein. For example, a non-transitory computer-readable medium (e.g., memory 1130) may store a set of instructions (e.g., one or more instructions or code) for execution by the processor 1120. The processor 1120 may execute the set of instructions to perform one or more operations or processes described herein. In some implementations, execution of the set of instructions, by one or more processors 1120, causes the one or more processors 1120 and/or the device 1100 to perform one or more operations or processes described herein. In some implementations, hardwired circuitry may be used instead of or in combination with the instructions to perform one or more operations or processes described herein. Additionally, or alternatively, the processor 1120 may be configured to perform one or more operations or processes described herein. Thus, implementations described herein are not limited to any specific combination of hardware circuitry and software.

The number and arrangement of components shown in FIG. 11 are provided as an example. The device 1100 may include additional components, fewer components, different components, or differently arranged components than those shown in FIG. 11. Additionally, or alternatively, a set of components (e.g., one or more components) of the device 1100 may perform one or more functions described as being performed by another set of components of the device 1100.

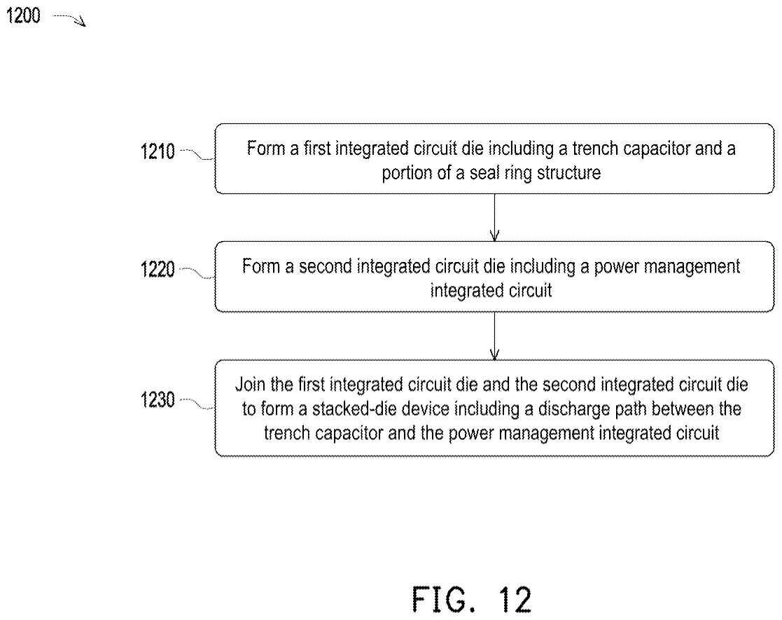

FIG. 12 is a flowchart of an example process 1200 associated with forming a semiconductor die package described herein. In some implementations, one or more process blocks of FIG. 11 are performed by one or more semiconductor processing tools (e.g., one or more of the semiconductor processing tools 102-114). Additionally, or alternatively, one or more process blocks of FIG. 11 may be performed by one or more components of device 1100, such as processor 1120, memory 1130, input component 1140, output component 1150, and/or communication component 1160.

As shown in FIG. 12, process 1200 may include forming a first integrated circuit die, including a trench capacitor and a portion of a seal ring structure (block 1210). For example, one or more of the semiconductor processing tools 102-114 may form a first integrated circuit die (e.g., the first semiconductor die 202) including a trench capacitor structure 220 and a portion of a seal ring structure (e.g., a portion of the inner seal ring structure 304), as described above.

As further shown in FIG. 12, process 1200 may include forming a second integrated circuit die including a power management integrated circuit (block 1220). For example, one or more of the semiconductor processing tools 102-114 may form a second integrated circuit die (e.g., the second semiconductor die 206) including a PMIC 312, as described above.

As further shown in FIG. 12, process 1200 may include joining the first integrated circuit die and the second integrated circuit die to form a stacked-die device including a discharge path between the trench capacitor and the power management integrated circuit, (block 1230). For example, one or more of the semiconductor processing tools 102-114 may join the first integrated circuit die (e.g., the first semiconductor die 202) and the second integrated circuit die (e.g., the second semiconductor die 206) to form a stacked-die device (e.g., the semiconductor die package 200) including a discharge path 322 between the trench capacitor structure 220 and the PMIC 312, as described above. In some implementations, the discharge path 312 includes the portion of the seal ring structure (e.g., the portion of the inner seal ring structure 304).

Process 1200 may include additional implementations, such as any single implementation or any combination of implementations described below and/or in connection with one or more other processes described elsewhere herein.

In a first implementation, the portion of the seal ring structure (e.g., the portion of the inner seal ring structure 304) connects with a voltage terminal (e.g., the negative polarity terminal 324 or the positive polarity terminal 326) of the PMIC 312.

In a second implementation, alone or in combination with the first implementation, the voltage terminal connects to an n-type contact 316 of an electrostatic discharge diode (e.g., the diode structure 320) or a p-type contact 318 of the electrostatic discharge diode.

In a third implementation, alone or in combination with one or more of the first and second implementations, the portion of the seal ring structure corresponds to a portion of an inner seal ring structure 304 of the stacked-die device (e.g., the semiconductor die package 200).

In a fourth implementation, alone or in combination with one or more of the first through third implementations, the discharge path corresponds to a discharge path for a diode source voltage.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

Some implementations herein describe apparatuses and techniques related to a semiconductor die package including a first IC die including capacitor circuitry bonded with a second IC die including logic circuitry. The semiconductor die package may include discharge paths incorporated into a seal ring structure spanning the first IC die and the second IC die. The discharge paths may lead to a power management integrated circuit (PMIC) included in the second IC die. During a bonding of the first IC die and the second IC die, the discharge paths incorporated into the seal ring structure may route an electrical discharge from the capacitor circuitry of the first IC die to the PMIC.

By including such discharge paths in the seal ring structure, a likelihood of damage to the logic circuitry of the second IC die during the bonding operation may be reduced relative to another semiconductor device not including the discharge paths. Further, and in this way, an amount of resources to manufacture a quantity of the semiconductor device (e.g., manufacturing tools, materials, and/or computing resources, among other examples) may be reduced.

As described in greater detail above, some implementations described herein provide a semiconductor die package. The semiconductor die package includes a first IC die. The first IC die includes a trench capacitor a first seal ring segment a second seal ring segment that is electrically isolated from the first seal ring segment. The semiconductor die package includes a second IC die connected with the first integrated circuit die. The second IC die includes a PMIC that incudes first voltage terminal corresponding to a first polarity and a second voltage terminal corresponding to a second polarity that is opposite the first polarity. The semiconductor die package includes a first electrically conductive trace connecting the trench capacitor, the first seal ring segment, and the first voltage terminal. The semiconductor die package includes a second electrically conductive trace connecting the trench capacitor, the second seal ring segment, and the second voltage terminal.

As described in greater detail above, some implementations described herein provide a semiconductor die package. The semiconductor die package includes a first IC die. The first IC die incudes a first trench capacitor, a second trench capacitor, a first seal ring segment, and a second seal ring segment that is electrically isolated from the first seal ring segment. The semiconductor die package includes a second IC die connected with the first IC die. The second IC die includes a PMIC. The PMIC includes a first voltage terminal corresponding to a first polarity and a second voltage terminal corresponding to a second polarity that is opposite the first polarity. The semiconductor die package includes a first electrically conductive trace connecting the first trench capacitor, the first seal ring segment, and the first voltage terminal. The semiconductor die package includes a second electrically conductive trace connecting the first trench capacitor, the second seal ring segment, and the second voltage terminal. The semiconductor die package includes a third electrically conductive trace connecting the second trench capacitor, the first seal ring segment, and the first voltage terminal.

As described in greater detail above, some implementations described herein provide a method. The method includes forming a first IC die that includes a trench capacitor and a portion of a seal ring structure. The method includes forming a second IC die that includes a power management integrated circuit. The method includes joining the first IC die and the second IC die to form a stacked-die device including a discharge path between the trench capacitor and the power management integrated circuit, where the discharge path includes the portion of the seal ring structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die package, comprising:
a first integrated circuit die, comprising:
a trench capacitor;
a first seal ring segment; and
a second seal ring segment that is electrically isolated from the first seal ring segment;
a second integrated circuit die connected with the first integrated circuit die and comprising:
a power management integrated circuit, comprising:
a first voltage terminal corresponding to a first polarity; and
a second voltage terminal corresponding to a second polarity that is opposite the first polarity;
a first electrically conductive trace connecting the trench capacitor, the first seal ring segment, and the first voltage terminal; and
a second electrically conductive trace connecting the trench capacitor, the second seal ring segment, and the second voltage terminal.

2. The semiconductor die package of claim 1, wherein the power management integrated circuit comprises:
a diode structure.

3. The semiconductor die package of claim 1, wherein the second integrated circuit die further comprises:
a device region including logic circuitry.

4. The semiconductor die package of claim 3, wherein the logic circuitry connects with the trench capacitor of the first integrated circuit die.

5. The semiconductor die package of claim 1, wherein the first seal ring segment corresponds to a first segment of an inner seal ring structure and the second seal ring segment corresponds to a second segment of the inner seal ring structure.

6. The semiconductor die package of claim 5, wherein the inner seal ring structure is located within a perimeter of an outer seal ring structure.

7. The semiconductor die package of claim 5, wherein a discharge path between the trench capacitor and the power management integrated circuit includes one or more portions of the inner seal ring structure.

8. The semiconductor die package of claim 5, wherein the first seal ring segment and the second seal ring segment are spaced apart by a gap between the first seal ring segment and the second seal ring segment.

9. The semiconductor die package of claim 8, wherein a width of the gap is included in a range of approximately 0.3 microns to approximately 0.5 microns.

10. A semiconductor die package, comprising:
a first integrated circuit die, comprising:
a first trench capacitor;
a second trench capacitor;
a first seal ring segment;
a second seal ring segment that is electrically isolated from the first seal ring segment;
a second integrated circuit die connected with the first integrated circuit die and comprising:
a power management integrated circuit, comprising:
a first voltage terminal corresponding to a first polarity; and
a second voltage terminal corresponding to a second polarity that is opposite the first polarity;
a first electrically conductive trace connecting the first trench capacitor, the first seal ring segment, and the first voltage terminal;
a second electrically conductive trace connecting the first trench capacitor, the second seal ring segment, and the second voltage terminal; and
a third electrically conductive trace connecting the second trench capacitor, the first seal ring segment, and the first voltage terminal.

11. The semiconductor die package of claim 10, wherein the first voltage terminal corresponds to a transistor source voltage terminal.

12. The semiconductor die package of claim 10, wherein the second voltage terminal corresponds to transistor drain voltage terminal.

13. The semiconductor die package of claim 10, wherein the power management integrated circuit further comprises a third voltage terminal corresponding to the second polarity and wherein the semiconductor die package further comprises:
a third seal ring segment that is electrically isolated from the first seal ring segment and the second seal ring segment;
a third trench capacitor; and
a fourth electrically conductive trace connecting the third trench capacitor, the third seal ring segment, and the third voltage terminal.

14. The semiconductor die package of claim 13, further comprising:
a fifth electrically conductive trace connecting the third trench capacitor, the second seal ring segment, and the second voltage terminal.

15. The semiconductor die package of claim 13, wherein the first seal ring segment, the second seal ring segment, and the third seal ring segment correspond to respective segments of an inner seal ring structure.

16. A method, comprising:
forming a first integrated circuit die, comprising:
a trench capacitor;
a portion of a seal ring structure; and
forming a second integrated circuit die, comprising:
a power management integrated circuit; and
joining the first integrated circuit die and the second integrated circuit die to form a stacked-die device including a discharge path between the trench capacitor and the power management integrated circuit,
wherein the discharge path includes the portion of the seal ring structure.

17. The method of claim 16, wherein the portion of the seal ring structure connects with a voltage terminal of the power management integrated circuit.

18. The method of claim 17, wherein the voltage terminal connects to an n-type contact of an electrostatic discharge diode or a p-type contact of the electrostatic discharge diode.

19. The method of claim 16, wherein the portion of the seal ring structure corresponds to a portion of an inner seal ring structure of the stacked-die device.
